(19) United States
(12) Patent Application Publication
(10) Pub. No.: US 2024/0414839 A1
(43) Pub. Date: Dec. 12, 2024

(54) MANUFACTURING METHOD OF PRINTED CIRCUIT BOARD

(71) Applicant: FUJIFILM Corporation, Tokyo (JP)

(72) Inventors: Norihide SHIMOHARA, Kanagawa (JP); Yusuke FUJII, Kanagawa (JP)

(73) Assignee: FUJIFILM Corporation, Tokyo (JP)

(21) Appl. No.: 18/809,276

(22) Filed: Aug. 19, 2024

Related U.S. Application Data
(63) Continuation of application No. PCT/JP2023/008610, filed on Mar. 7, 2023.

(30) Foreign Application Priority Data
Mar. 29, 2022 (JP) 2022-052925

(51) Int. Cl. H05K 1/02; H05K 3/12

(52) U.S. Cl. CPC H05K 1/0219; H05K 3/125; H05K 2201/0723

(57) ABSTRACT

Provided is a manufacturing method of a printed circuit board, which has excellent coverage of an electromagnetic wave shielding layer and excellent electromagnetic wave shielding characteristics. A manufacturing method of a printed circuit board that includes a printed wiring board having a ground wiring line, at least one semiconductor device mounted in a region surrounded by the ground wiring line on the printed wiring board, an insulating layer that embeds at least one of the semiconductor device, is disposed inside the ground wiring line, and has an inclined part at an outer edge, and an electromagnetic wave shielding layer disposed on the insulating layer, the method includes a step of forming, on the printed wiring board on which the semiconductor device is mounted, a layer by gradually reducing an outer edge of a jetting region of an insulating ink from a printed wiring board side such that the inclined part is formed to form the insulating layer having the inclined part, in a case where the layer is laminated by performing a step of forming the layer by jetting the insulating ink with an ink jet a plurality of times; and a step of forming, on the insulating layer, the electromagnetic wave shielding layer by jetting a conductive ink with an ink jet.

### CROSS-REFERENCE TO RELATED APPLICATIONS

This application is a Continuation of PCT International Application No. PCT/JP2023/008610 filed on Mar. 7, 2023, which claims priority under 35 U.S.C. § 119 (a) to Japanese Patent Application No. 2022-052925 filed on Mar. 29, 2022. The above applications are hereby expressly incorporated by reference, in their entirety, into the present application.

### BACKGROUND OF THE INVENTION

### 1. Field of the Invention

The present invention relates to a manufacturing method of a printed circuit board having a semiconductor device mounted in a region surrounded by a ground wiring line on a printed wiring board, and particularly, to a manufacturing method of a printed circuit board that embeds the semiconductor device and forms an insulating layer having an inclined part and an electromagnetic shielding layer that covers the insulating layer.

### 2. Description of the Related Art

A semiconductor device or the like may be hindered from normal operation by receiving electromagnetic interference, which may result in malfunction. In addition, in a case where the semiconductor device or the like generates the electromagnetic wave, there is also a possibility that the electromagnetic wave may interfere with other semiconductor devices or electronic components and hinder normal operation.

Therefore, it is necessary to shield the electromagnetic waves in order to avoid electromagnetic interference from other electronic devices or to avoid electromagnetic interference with other electronic devices. In general, a semiconductor device or the like, which is a target to be shielded from electromagnetic waves, is shielded from the electromagnetic waves by being covered with a shielding can. The shielding can has problems such as being thick, heavy, and having a small degree of freedom in design, and thus, there is a demand for an alternative technique for the shielding can. For example, an insulating layer and an electromagnetic wave shielding layer are laminated to form an electromagnetic wave on a printed wiring board on which a semiconductor device is mounted.

For example, JP2019-527463A describes a method of manufacturing a printed circuit board having a track that is electromagnetically shielded, using an ink jet printer. In JP2019-527463A, a printed circuit board having an electromagnetically shielded track is formed using a first ink jet printing head and a second printing head, an insulating resin ink forms a sleeve around the conductive track, a first metal-containing ink forms a shielding sleeve around the insulating resin sleeve, and/or a housing is formed around the conductive track, and a first metal-containing ink forms a shielding capsule around an insulating resin housing.

### SUMMARY OF THE INVENTION

In the method of manufacturing the printed circuit board using the ink jet printer described in JP2019-527463A, coverage of an electromagnetic wave shielding layer is deteriorated, and as a result, the electromagnetic wave shielding characteristics are also deteriorated, and thus it is necessary to improve the coverage and the electromagnetic wave shielding characteristics.

An object of the present invention is to provide a manufacturing method of a printed circuit board, which solves the problems based on the related art described above, and has excellent coverage and excellent electromagnetic wave shielding characteristics of an electromagnetic wave shielding layer.

In order to achieve the above-described object, the invention [1] provides a manufacturing method of a printed circuit board that includes a printed wiring board having a ground wiring line, at least one semiconductor device mounted in a region surrounded by the ground wiring line on the printed wiring board, an insulating layer that embeds at least one of the semiconductor device, is disposed in the region surrounded by the ground wiring line, and has an inclined part at an outer edge, and an electromagnetic wave shielding layer disposed on the insulating layer, the method including a step of forming, on the printed wiring board on which the semiconductor device is mounted, a layer by gradually reducing an outer edge of a jetting region of an insulating ink such that the inclined part is formed to form the insulating layer having the inclined part, in a case where the layer is laminated by performing a step of forming the layer by jetting the insulating ink with an ink jet a plurality of times; and a step of forming, on the insulating layer, the electromagnetic wave shielding layer by jetting a conductive ink with an ink jet.

The invention [2] provides the manufacturing method of a printed circuit board according to invention [1], in which a shortest distance between the semiconductor device and the ground wiring line is 0.2 to 1.0 mm.

The invention [3] provides the manufacturing method of a printed circuit board according to invention [1] or [2], in which the inclined part has a maximum angle of 85° or less.

The invention [4] provides the manufacturing method of a printed circuit board according to any one of inventions [1] to [3], in which the inclined part has a maximum angle of 75° or less.

The invention [5] provides the manufacturing method of a printed circuit board according to any one of inventions [1] to [4], in which the semiconductor device has a side surface perpendicular to a surface of the printed wiring board, and a height of the semiconductor device from the surface of the printed wiring board is 0.5 mm or more.

According to the present invention, it is possible to provide a manufacturing method of a printed circuit board, in which the electromagnetic wave shielding layer has excellent coverage and excellent electromagnetic wave shielding characteristics.

### BRIEF DESCRIPTION OF THE DRAWINGS

FIG. 1 is a schematic plan view showing one step of a first example of a manufacturing method of a printed circuit board according to an embodiment of the present invention.

FIG. 2 is a schematic plan view showing one step of the first example of the manufacturing method of a printed circuit board according to the embodiment of the present invention.

FIG. 3 is a schematic plan view showing one step of the first example of the manufacturing method of a printed circuit board according to the embodiment of the present invention.

FIG. 4 is a schematic cross-sectional view showing one step of the first example of the manufacturing method of a printed circuit board according to the embodiment of the present invention.

FIG. 5 is a schematic cross-sectional view showing one step of the first example of the manufacturing method of a printed circuit board according to the embodiment of the present invention.

FIG. 6 is a schematic cross-sectional view showing one step of the first example of the manufacturing method of a printed circuit board according to the embodiment of the present invention.

FIG. 7 is a schematic perspective view showing an example of a print image used for forming an insulating layer in the manufacturing method of a printed circuit board according to the embodiment of the present invention.

FIG. 8 is a schematic cross-sectional view showing one step of an example of a method of forming the insulating layer in the manufacturing method of a printed circuit board according to the embodiment of the present invention.

FIG. 9 is a schematic cross-sectional view showing one step of an example of the method of forming the insulating layer in the manufacturing method of a printed circuit board according to the embodiment of the present invention.

FIG. 10 is a schematic cross-sectional view showing one step of an example of the method of forming the insulating layer in the manufacturing method of a printed circuit board according to the embodiment of the present invention.

FIG. 11 is a schematic cross-sectional view showing one step of an example of the method of forming the insulating layer in the manufacturing method of a printed circuit board according to the embodiment of the present invention.

FIG. 12 is a schematic plan view showing one step of a second example of the manufacturing method of a printed circuit board according to the embodiment of the present invention.

FIG. 13 is a schematic plan view showing one step of the second example of the manufacturing method of a printed circuit board according to the embodiment of the present invention.

FIG. 14 is a schematic plan view showing one step of the second example of the manufacturing method of a printed circuit board according to the embodiment of the present invention.

FIG. 15 is a schematic cross-sectional view showing one step of the second example of the manufacturing method of a printed circuit board according to the embodiment of the present invention.

FIG. 16 is a schematic cross-sectional view showing one step of the second example of the manufacturing method of a printed circuit board according to the embodiment of the present invention.

FIG. 17 is a schematic cross-sectional view showing one step of the second example of the manufacturing method of a printed circuit board according to the embodiment of the present invention.

FIG. 18 is a schematic view showing another example of a configuration of the insulating layer of the printed circuit board according to the embodiment of the present invention.

### DESCRIPTION OF THE PREFERRED EMBODIMENTS

Hereinafter, the manufacturing method of the printed circuit board according to the embodiment of the present invention will be described in detail based on a suitable embodiment shown in the accompanying drawings.

Note that the drawings to be described below are examples showing the present invention, and the present invention is not limited to the drawings shown below.

In the following description, “to” indicating a numerical range includes numerical values described on both sides thereof. For example, in a case where ε is in a range of a numerical value ε_{α} to a numerical value ε_{β}, a range of ε is a range including the numerical value ε_{α} and the numerical value ε_{β} and is represented by ε_{α}≤ε≤ε_{β} in mathematical symbols.

Angles described as, for example, “an angle represented by a specific numerical value”, “parallel”, and “perpendicular” include error ranges generally tolerated in the art unless otherwise described.

In addition, also in the description of a temperature and a time, the temperature and the time include an error range generally allowed in the related art unless otherwise specified.

The “step” includes not only an independent step but also a step that cannot be clearly distinguished from other steps, as long as the intended purpose of the step is achieved.

In addition, in a case in which a plurality of substances corresponding to respective components in a composition are present, the amount of the respective components in the composition means the total amount of the plurality of substances present in the composition unless otherwise specified.

In addition, hereinafter, unless otherwise specified, the ink jet means an ink jet recording method.

### [First Example of Manufacturing Method of Printed Circuit Board]

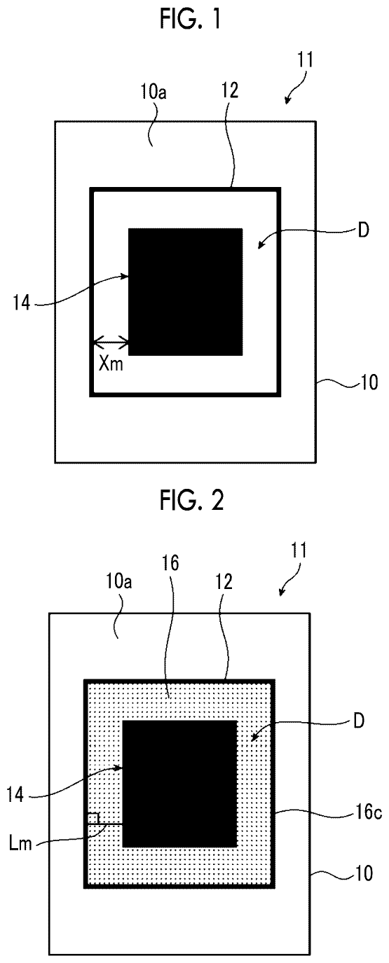

FIGS. 1 to 3 are schematic plan views showing a first example of the manufacturing method of a printed circuit board of the embodiment of the present invention in the order of steps. FIGS. 4 to 6 are schematic cross-sectional views showing the first example of the manufacturing method of a printed circuit board of the embodiment of the present invention in the order of steps. FIGS. 1 and 4, FIGS. 2 and 5, and FIGS. 3 and 6 show the same steps, respectively.

In FIGS. 1 to 6, the ground wiring line 12 is disposed in a quadrangular shape on the surface 10a of the printed wiring board 10. Although the case where one semiconductor device 14 is mounted in the region D surrounded by the ground wiring line 12 will be described as an example, an embodiment of the present invention is not limited to this configuration.

The printed wiring board 10 on which the semiconductor device 14 is mounted in the region D surrounded by the ground wiring line 12 as shown in FIGS. 1 and 4 is also referred to as a processing substrate 11. Various circuits, electronic components, electronic elements, and the like (not shown) are mounted on the printed wiring board 10 in addition to the semiconductor device 14.

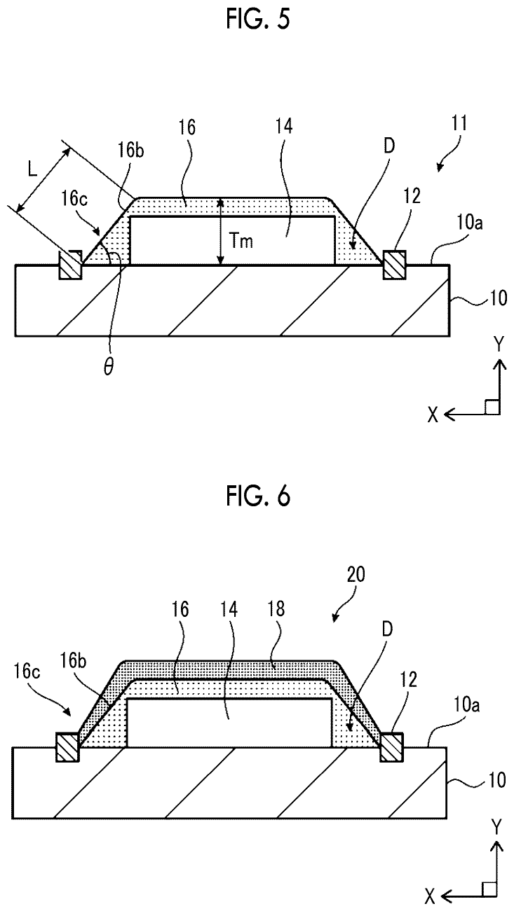

Next, as shown in FIGS. 2 and 5, on the processing substrate 11 in FIGS. 1 and 4, an insulating layer 16 that embeds the semiconductor device 14, is disposed in the region D surrounded by the ground wiring line 12, and has the inclined part 16b at an outer edge 16c is formed.

In the step of forming the insulating layer 16, a layer is formed, on the surface 10a of the printed wiring board 10 on which the semiconductor device 14 is mounted, by gradually reducing the outer edge of the jetting region of the insulating ink such that the inclined part 16b is formed to form the insulating layer 16 having the inclined part 16b in a case where the layer is laminated by performing a step of forming the layer (not shown) by jetting the insulating ink (not shown) with an ink jet a plurality of times. The step of forming the insulating layer 16 will be described in more detail later.

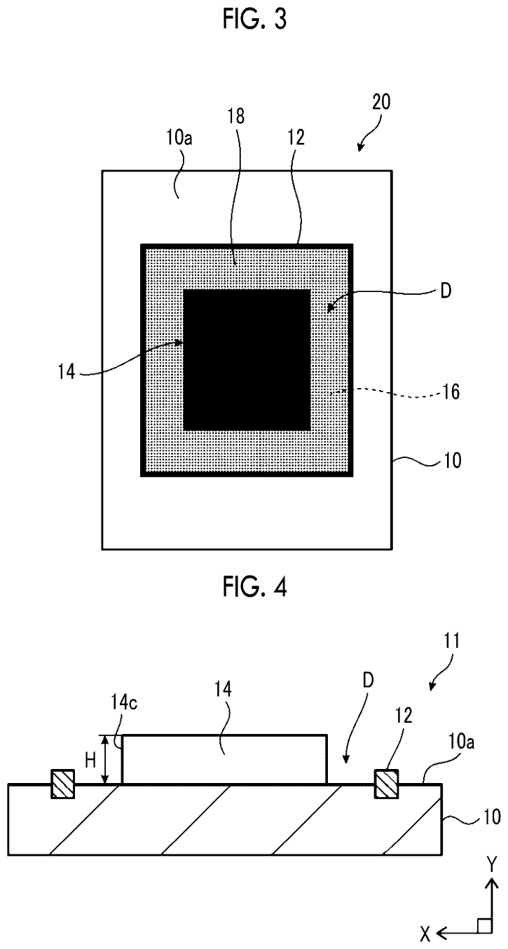

After the insulating layer 16 is formed on the processing substrate 11, as shown in FIGS. 3 and 6, the conductive ink (not shown) is jetted with an ink jet onto the insulating layer 16 having the inclined part 16b to form the electromagnetic wave shielding layer 18 having conductivity. The electromagnetic wave shielding layer 18 covers the entire surface of the insulating layer 16 and is connected to the ground wiring line 12. The electromagnetic wave shielding layer 18 is in a state of being electrically connected to the ground wiring line 12. In this manner, the printed circuit board 20 is manufactured.

The printed circuit board 20 includes the printed wiring board 10 having the ground wiring line 12, one semiconductor device 14 mounted in the region D surrounded by the ground wiring line 12 on the printed wiring board 10, the insulating layer 16 that embeds the semiconductor device 14 and is disposed in the region D surrounded by the ground wiring line 12 and has the inclined part 16b at the outer edge 16c, and the electromagnetic wave shielding layer 18 disposed on the insulating layer 16.

In the manufacturing method of the printed circuit board 20, in a configuration in which the insulating layer 16 and the electromagnetic wave shielding layer 18 are laminated and formed in the region D surrounded by the ground wiring line 12 on the surface 10a of the printed wiring board 10 on which the semiconductor device 14 is mounted, in order to enhance the electromagnetic wave shielding properties, the coverage of the electromagnetic wave shielding layer 18 with respect to the insulating layer 16 is required, and the electromagnetic wave shielding layer 18 needs to be adhered to the side surface of the insulating layer 16. In the ink jet recording method of jetting the conductive ink from the upper part of the insulating layer 16 to form the electromagnetic wave shielding layer 18, in a case of the insulating layer disposed to thinly cover the semiconductor device 14 that does not have the inclined part, it is difficult to apply the conductive ink to a side surface of the insulating layer that does not have the inclined part.

In a case where the side surface 14c of the semiconductor device 14 having a height is perpendicular, the conductive ink is less likely to adhere in the ink jet recording method, which causes a decrease in electromagnetic wave shielding properties. By providing the insulating layer 16 with the inclined part 16b, the adhesiveness of the conductive ink to the insulating layer 16 can be improved, and the coverage of the formed electromagnetic wave shielding layer 18 can be excellent. As a result, the surface defects of the electromagnetic wave shielding layer 18 can be reduced, and the electromagnetic wave shielding properties can be improved.

### (Forming Method of Insulating Layer)

Next, the step of forming the insulating layer 16 will be described in more detail.

The insulating layer 16 is formed by performing the step of jetting the insulating ink with an ink jet to form a layer a plurality of times as described above, and has a multilayer structure in which a plurality of layers are laminated. In the formation of the insulating layer 16, a plurality of layers need to be set in advance. The number of layers for forming the insulating layer 16 is not particularly limited, and is, for example, 2 to 7 layers.

As a method of setting the plurality of layers described above, for example, the insulating layer 16 is divided into a plurality of layers having a thickness in a direction Y perpendicular to the surface 10a of the printed wiring board 10 to set the plurality of layers. Each layer is a layer in which the insulating layer 16 is cut along the direction X parallel to the surface 10a of the printed wiring board 10.

For each layer, an image, as viewed from the surface 10a side, of the printed wiring board 10 representing each layer is set as a print image. The image area of the print image is used as the jetting region, and insulating ink is applied with an ink jet to form each layer. Since each layer has a thickness in the direction Y as described above, the step of applying the insulating ink is repeated a plurality of times using one print image to form the layer. In a case where the insulating layer 16 is divided into an extremely large number of layers, it is necessary to prepare the print image for the number of divisions. The higher the number of divisions of the insulating layer 16, the higher the accuracy with which the insulating layer 16 can be formed, but the number of image data required for forming the insulating layer 16 is increased. Therefore, the number of divisions of the insulating layer 16 is appropriately determined in consideration of the time for producing the image data prepared at the time of forming the insulating layer 16.

Next, an acquiring method of a print image for each layer constituting the insulating layer 16 will be described. Hereinafter, as a specific example, a case where the insulating layer 16 shown in FIGS. 2 and 5 is configured of four layers will be described.

First, three-dimensional shape data of the processing substrate 11 shown in FIGS. 1 and 4, on which the insulating layer 16 is formed, is acquired.

The acquiring method of the three-dimensional shape data is not particularly limited, and for example, a microscope or a three-dimensional scanner is used.

Next, slice data of a height of the printed wiring board 10 in the direction Y from the surface 10a is acquired from the three-dimensional shape data. At this time, the image is converted into a reversed image in which a portion of the semiconductor device 14 is white. The processing of converting the above-described image into the reversed image with the white background is processing of removing the semiconductor device 14 from the jetting region of the insulating ink.

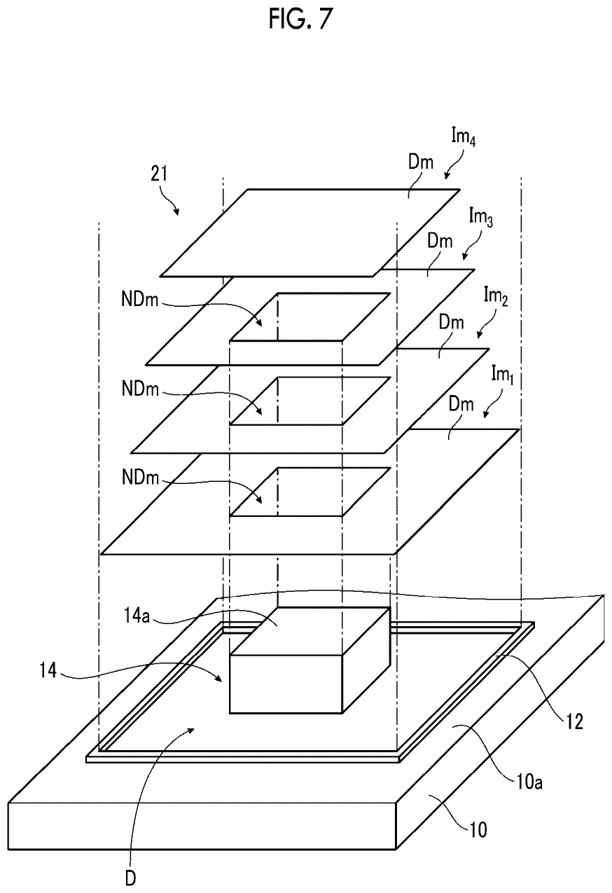

In a case where the insulating layer 16 is configured of four layers as described above, four print images are required in order to set a jetting region for jetting the insulating ink with an ink jet. Using the slice data described above, the first image Im₁ to the fourth image Im₄ shown in FIG. 7 described below are set as four print images.

In a case where the insulating layer 16 is configured of four layers, the layers are referred to as a first layer, a second layer, a third layer, and a fourth layer from the printed wiring board 10 side.

Here, FIG. 7 is a schematic perspective view showing an example of a print image used for forming the insulating layer in the manufacturing method of a printed circuit board according to the embodiment of the present invention.

The print image representing the first layer in contact with the surface 10a of the printed wiring board 10 is defined as a first image Im₁ (refer to FIG. 7) having an outer edge in contact with the ground wiring line 12. The first image Im₁ is not a solid image, and is an image in which the semiconductor device 14 is set as a non-image area NDm and a periphery of the semiconductor device 14 is set as an image area Dm. The image area Dm of the first image Im₁ is a jetting region of the insulating ink.

Next, a print image representing the second layer on the first layer is set. The print image representing the second layer is defined as a second image Im₂ (refer to FIG. 7) in which an outer edge is set to a side of the side surface 14c of the semiconductor device 14 with respect to the ground wiring line 12. The second image Im₂ is not a solid image similarly to the first image Im₁, and is an image in which the semiconductor device 14 is defined as a non-image area NDm and the periphery of the semiconductor device 14 is defined as an image area Dm. The second image Im₂ has a smaller outer edge than the first image Im₁. That is, the outer edge of the image area Dm is smaller, and the outer edge of the jetting region of the insulating ink in the second image Im₂ is smaller than that in the first image Im₁.

Next, a print image representing the third layer on the second layer is set. The print image representing the third layer is defined as a third image Im₃ (refer to FIG. 7) in which an outer edge is set to a side of the side surface 14c of the semiconductor device 14 with respect to the second image Im₂. The third image Im₃ (refer to FIG. 7) is not a solid image similarly to the first image Im₁, and is an image in which the semiconductor device 14 is defined as a non-image area NDm and the periphery of the semiconductor device 14 is defined as an image area Dm. The third image Im₃ has a smaller outer edge than the second image Im₂. That is, the outer edge of the image area Dm is smaller, and the outer edge of the jetting region of the insulating ink in the third image Im₃ is smaller than that in the second image Im₂.

Next, a print image representing the fourth layer on the third layer is set. The fourth layer is a layer that covers the upper surface 14a of the semiconductor device 14. The print image representing the fourth layer is defined as a fourth image Im₄ (refer to FIG. 7) in which an outer edge is set to a side of the side surface 14c of the semiconductor device 14 with respect to the third image Im₃. The fourth image is a solid image and is an image in which a region that covers the upper surface 14a of the semiconductor device 14 is defined as an image area Dm. The fourth image Im₄ has a smaller outer edge than the third image Im₃. That is, the outer edge of the image area Dm is smaller, and the outer edge of the jetting region of the insulating ink in the fourth image Im₄ is smaller than that in the third image Im₃.

In this way, the outer edges of the jetting regions of the insulating ink of the first image Im₁ to the fourth image Im₄ are set to be gradually reduced from the printed wiring board 10 side. It should be noted that the first image Im₁ to the fourth image Im₄ are all set such that the image area Dm is set in the region D shown in FIG. 1.

As described above, the first image Im₁ to the third image Im₃ shown in FIG. 7 include the image area Dm and the non-image area NDm, the image area Dm is a jetting region of the insulating ink, and the non-image area NDm is a region in which the insulating ink is not jetted, and corresponds to a region corresponding to the semiconductor device 14.

The fourth image Im₄ is a solid image as described above, and is only the image area Dm. The fourth image Im₄ is used for the jetting of the insulating ink to the region that covers the upper surface 14a of the semiconductor device 14.

The insulating layer 16 is formed using an image set 21 including the first image Im₁ to the fourth image Im₄ described above.

A forming step of the insulating layer 16 using the first image Im₁ to the fourth image Im₄ shown in FIG. 7 will be described.

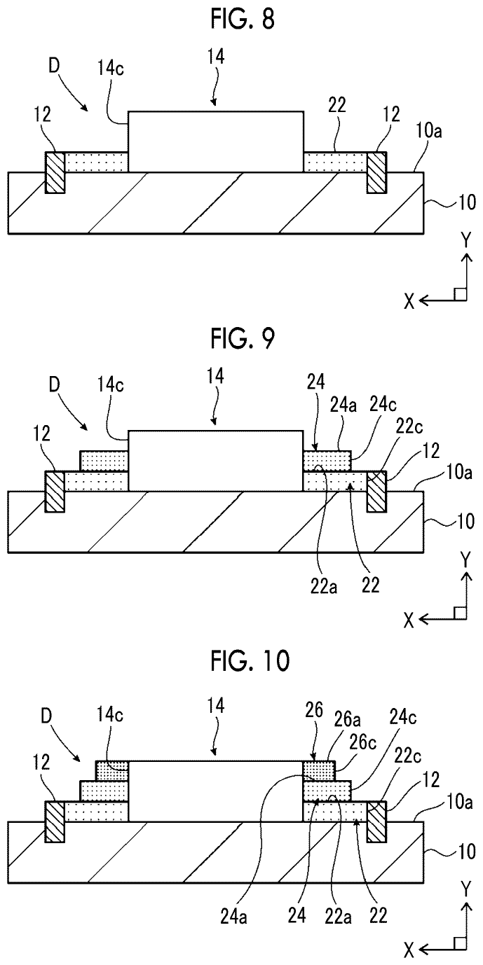

FIGS. 8 to 11 are schematic cross-sectional views showing an example of a forming method of an insulating layer of the manufacturing method of a printed circuit board of the embodiment of the present invention in the order of steps. It should be noted that, in FIGS. 8 to 11, the same configurations as the configurations shown in FIGS. 1 to 6 are designated by the same reference numerals, and the detailed description thereof will be omitted.

First, the jetting region of the insulating ink by the ink jet is set for each image of the first image Im₁ to the fourth image Im₄. The ink jet is used for forming the insulating layer and the electromagnetic wave shielding layer, and the insulating ink and the conductive ink are jetted using the ink jet recording device. The ink jet recording device stores image information of the first image Im₁ to the fourth image Im₄, and sets the droplet position of the insulating ink for each image. In addition, in the ink jet recording device, the droplet position of the conductive ink is set for the electromagnetic wave shielding layer in the same manner as for the conductive layer.

Next, on the surface 10a of the printed wiring board 10, the insulating ink is jetted with an ink jet onto the jetting region corresponding to the image area Dm of the first image Im₁ to form a first layer 22 shown in FIG. 8. In a case where the first layer 22 has a thickness in the direction Y, and the first layer 22 cannot be formed only by applying the insulating ink based on the first image Im₁ once, the application of the insulating ink by the ink jet based on the first image Im₁ is repeatedly performed until the thickness of the first layer 22 is obtained.

After the first layer 22 is formed, the insulating ink is jetted with an ink jet onto the jetting region corresponding to the image area Dm of the second image Im₂ on the surface 22a of the first layer 22 to form the second layer 24 shown in FIG. 9. In a case where the second layer 24 has a thickness in the direction Y as in the first layer 22, and the second layer 24 cannot be formed only by applying the insulating ink based on the second image Im₂ once, the application of the insulating ink by the ink jet based on the second image Im₂ is repeatedly performed until the thickness of the second layer 24 is obtained.

After the second layer 24 is formed, the insulating ink is jetted with an ink jet onto the jetting region corresponding to the image area Dm of the third image Im₃ on the surface 24a of the second layer 24 to form the third layer 26 shown in FIG. 10. In a case where the third layer 26 has a thickness in the direction Y as in the first layer 22, and the third layer 26 cannot be formed only by applying the insulating ink based on the third image Im₃ once, the application of the insulating ink by the ink jet based on the third image Im₃ is repeatedly performed until the thickness of the third layer 26 is obtained.

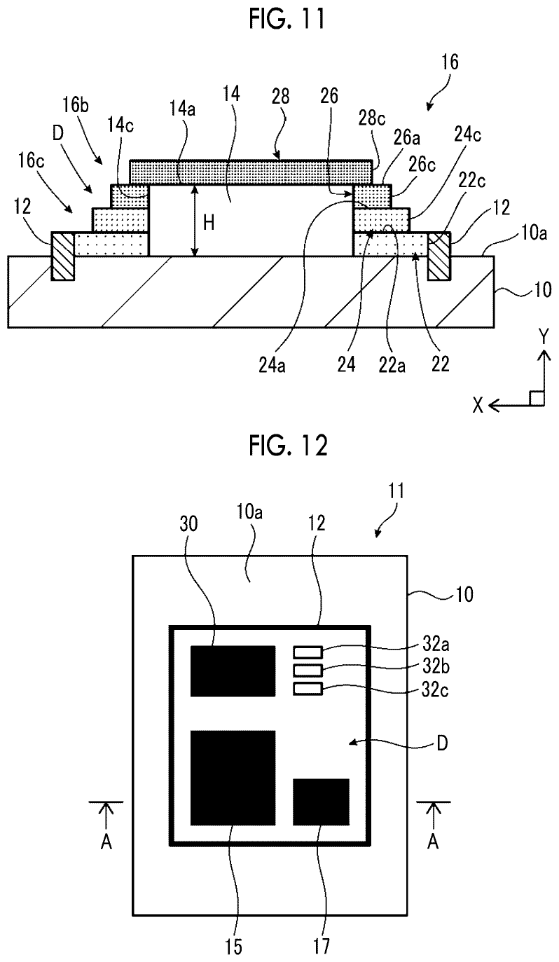

After the third layer 26 is formed, the insulating ink is jetted with an ink jet onto the jetting region corresponding to the image area Dm of the fourth image Im₄ on the surface 26a of the third layer 26 to form the fourth layer 28 shown in FIG. 11. In a case where the fourth layer 28 has a thickness in the direction Y as in the first layer 22, and the fourth layer 28 cannot be formed only by applying the insulating ink based on the fourth image Im₄ once, the application of the insulating ink by the ink jet based on the fourth image Im₄ is repeatedly performed until the thickness of the fourth layer 28 is obtained. The fourth image Im₄ is a solid image, and the fourth layer 28 is a solid film. In the above-described manner, the insulating layer 16 is formed.

The outer edge 22c of the first layer 22, the outer edge 24c of the second layer 24, the outer edge 26c of the third layer 26, and the outer edge 28c of the fourth layer 28 are close to the side surface 14c of the semiconductor device 14 in this order, and the outer edge of the jetting region of the insulating ink is gradually reduced from the printed wiring board 10 side. That is, the first layer 22 to the fourth layer 28 are formed with the outer edge being gradually reduced, whereby the insulating layer 16 has a configuration in which the inclined part 16b is provided.

The inclined part 16b of the insulating layer 16 preferably has a maximum angle of 85° or less, and more preferably has a maximum angle of 75° or less. Therefore, in the above-described first layer to the fourth layer, it is preferable to set the position and the thickness of the outer edge such that the maximum angle of the inclined part 16b is 85° or less. It is preferable to set the first image Im₁ to the fourth image Im₄ as described above according to the set first layer to the fourth layer.

In addition, a length L (refer to FIG. 5) of the inclined part 16b of the insulating layer 16 is preferably 1.004/1 to 2/1, more preferably 1.015/1 to 1.411/1, and still more preferably 1.035/1 to 1.155/1 the thickness Tm (refer to FIG. 5) of the insulating layer 16.

A length L (refer to FIG. 5) of the inclined part 16b of the insulating layer 16 has a relationship of L=Tm×cosec θ with respect to the thickness Tm (refer to FIG. 5) of the insulating layer 16 and the angle θ of the inclined part 16b.

In order to form the insulating layer 16, each layer constituting the insulating layer is formed by gradually reducing the outer edge of the jetting region of the insulating ink, and the outer edge of the layer is gradually reduced from the printed wiring board side. In addition, the number of stages of reducing the outer edge may be 2 or more, preferably 3 or more, more preferably 4 or more, and still more preferably 6 or more. In a case where the number of stages of reducing the outer edge of the layer is large, the insulating layer 16 is formed using a large number of layers, whereby the maximum angle of the inclined part 16b of the formed insulating layer 16 can be reduced.

In a case where the number of stages of reducing the outer edge is 2, for example, in a case where the insulating layer is formed of four layers, two layers may be formed to have the same size, and then two layers may be formed to have the same size on the two layers formed first with the outer edge of the jetting region of the insulating ink being reduced. In addition, after the three layers may be formed to have the same size, one layer may be formed on the two layers formed first, with the outer edge of the jetting region of the insulating ink being reduced. In addition, in the stages of reducing the outer edge, the outer edge of the jetting region of the insulating ink may be sequentially reduced for each layer. For example, in a case where the insulating layer is formed of four layers, the outer edge of the jetting region of the insulating ink may be reduced for each layer.

### [Second Example of Manufacturing Method of Printed Circuit Board]

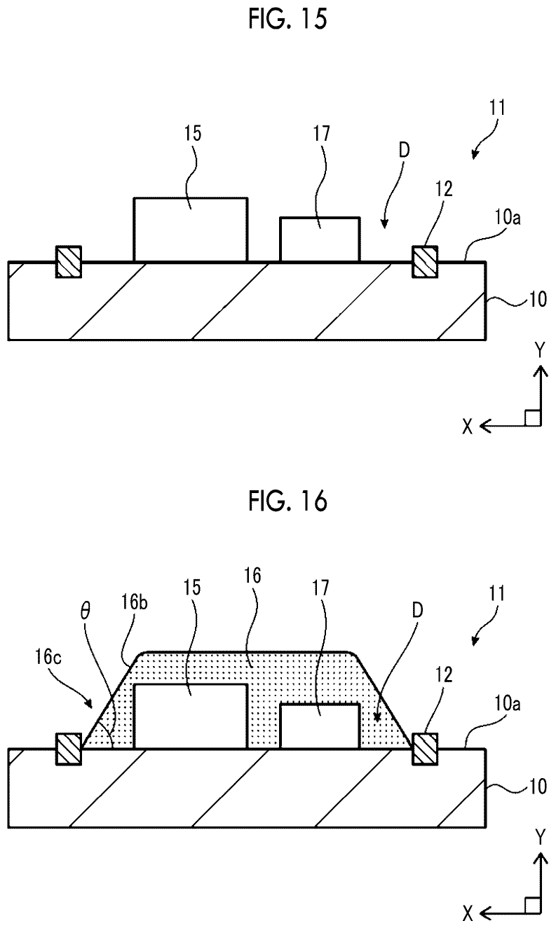

FIGS. 12 to 14 are schematic plan views showing a second example of the manufacturing method of a printed circuit board of the embodiment of the present invention in the order of steps. FIGS. 15 to 17 are schematic cross-sectional views showing the second example of the manufacturing method of a printed circuit board of the embodiment of the present invention in the order of steps. FIGS. 15 to 17 show cross sections taken along the line A-A of FIGS. 12 to 14. In addition, FIGS. 12 and 15, FIGS. 13 and 16, and FIGS. 14 and 17 show the same steps, respectively.

It should be noted that, in FIGS. 12 to 17, the same configurations as the configurations shown in FIGS. 1 to 6 are designated by the same reference numerals, and the detailed description thereof will be omitted.

In the processing substrate 11 shown in FIG. 12, the number of semiconductor devices mounted is different from that of the processing substrate 11 shown in FIG. 1, and the other configurations are the same as those of the processing substrate 11 shown in FIG. 1.

In the processing substrate 11 shown in FIG. 12, the semiconductor device 15, the semiconductor device 17, the semiconductor device 30, and the semiconductor devices 32a, 32b, and 32c are mounted in the region D on the surface 10a of the printed wiring board 10. In addition, although not shown, electronic components other than the semiconductor device, for example, a capacitor, a resistance element, and a coil element, are mounted in the region D. For example, the semiconductor device 15, the semiconductor device 17, the semiconductor device 30, and the semiconductor devices 32a, 32b, and 32c are different from each other, and a specific function is exhibited by the plurality of semiconductor devices and the electronic components.

The semiconductor device 17 is higher than the semiconductor device 15, as shown in FIG. 15.

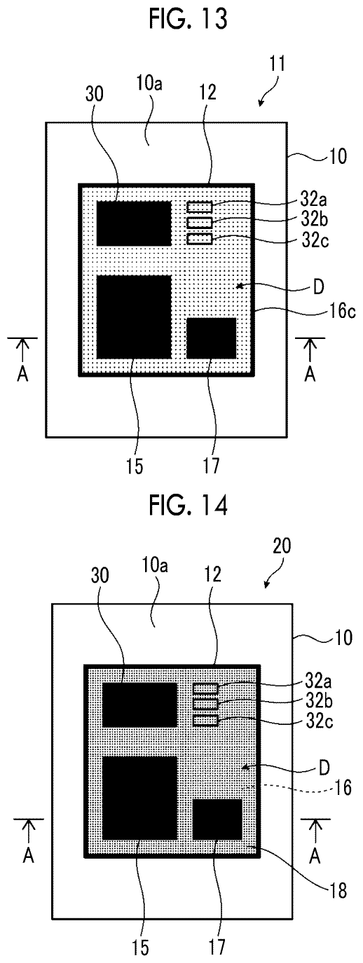

Next, as shown in FIGS. 13 and 16, an insulating layer 16 having an inclined part 16b (refer to FIG. 16) is formed in the region D.

Since the forming method of the insulating layer 16 is as described above, the detailed description thereof will be omitted. In a rough manner, three-dimensional shape data of the processing substrate 11 is acquired to obtain slice data. The number of layers for forming the insulating layer 16 and the thickness of each layer in the direction Y are set. The print image of the set number of layers is obtained from the slice data. The insulating ink is jetted with an ink jet based on the print image representing each layer to form each layer, thereby forming an insulating layer 16.

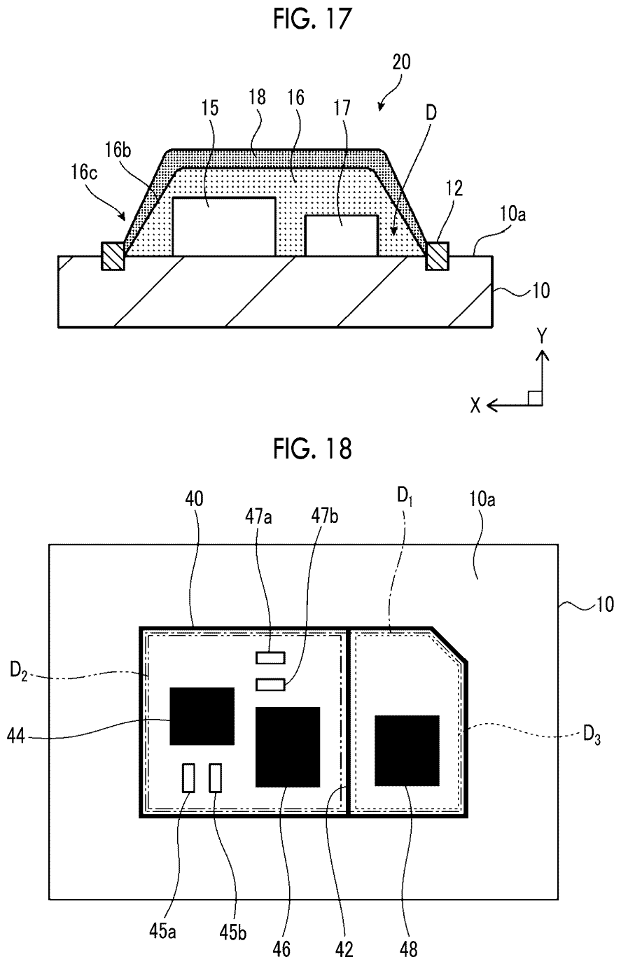

Next, as shown in FIGS. 14 and 17, the conductive ink is jetted with an ink jet onto the insulating layer 16 to form an electromagnetic wave shielding layer 18. The electromagnetic wave shielding layer 18 covers the entire surface of the insulating layer 16 and is in an electrically connected state with the ground wiring line 12. In this manner, the printed circuit board 20 on which the plurality of semiconductor devices are mounted is manufactured.

Next, the printed wiring board, the semiconductor device, the insulating layer, and the electromagnetic wave shielding layer constituting the printed circuit board will be described.

### (Printed Wiring Board)

The printed wiring board is not particularly limited, and for example, a flexible print substrate, a rigid print substrate, and a rigid flexible substrate can be used, and commercially available products can be appropriately used. The printed wiring board may have a monolayer structure or a multilayer structure.

In addition, the printed wiring board is made of, for example, glass epoxy, ceramics, polyimide, or polyethylene terephthalate.

The wiring line (not shown) of the printed wiring board is not particularly limited, but is preferably a copper wiring from the viewpoint of conductivity.

A printed wiring board is supplied with a voltage or a current from the outside in order to drive a circuit configured of the semiconductor device or the like. In addition, the printed wiring board has also a configuration in which a signal is input from the outside to a circuit configured by the semiconductor device or the like, or a signal is output from the circuit to the outside.

### <Ground Wiring Line>

The ground wiring line 12 of the printed wiring board 10 is a wiring line connected to a ground (GND) potential.

The ground wiring line 12 is consecutively disposed on the surface 10a of the printed wiring board 10 and is disposed in a closed shape. In FIGS. 1 and 2, in a case where the surface 10a of the printed wiring board 10 is viewed, the ground wiring line 12 is disposed in a quadrangular shape, but the disposition of the ground wiring line 12 is not limited to this, and the ground wiring line 12 may be disposed in a triangular shape, a polygonal shape having five or more sides, or a circular shape, and the disposition of the ground wiring line 12 is determined according to the mounting position of the semiconductor device and the electronic component. In a case where there are a plurality of the semiconductor devices, the ground wiring line 12 may be disposed to pass between the semiconductor devices.

The ground wiring line 12 is not limited to those consecutively disposed on the surface 10a of the printed wiring board 10 as shown in FIG. 1. For example, in a case where the surface 10a of the printed wiring board 10 is viewed, the ground wiring line 12 may have a nonconsecutive form such as a dotted line, or may be disposed in the nonconsecutive form and in a closed shape such as a quadrangle.

In addition, as shown in FIG. 4, the ground wiring line 12 is disposed to be partially embedded in the printed wiring board 10, but the present disclosure is not limited to this. The ground wiring line 12 may be formed on the surface 10a of the printed wiring board 10 without being partially embedded in the printed wiring board 10. In addition, the ground wiring line 12 may have a configuration in which a portion thereof penetrates the printed wiring board 10 in the direction Y.

### (Insulating Layer)

An insulating layer has electrical insulating properties, and electrically insulates a semiconductor device or the like in a region D surrounded by the ground wiring line 12 shown in FIG. 1 from the outside. The electrical insulating properties mean that a volume resistivity is 10¹⁰ Ωcm or more.

The insulating layer includes an inclined part at an outer edge. The inclined part is for maintaining a coating film thickness of the conductive ink or for enhancing the adhesiveness, and for enhancing the electromagnetic wave shielding properties of the electromagnetic wave shielding layer. From the viewpoint of maintaining the coating film thickness of the conductive ink or enhancing the adhesiveness, the maximum angle of the inclined part is preferably 85° or less, more preferably 80° or less, still more preferably 75° or less, and even more preferably 70° or less. The lower limit thereof is not particularly limited, but is preferably 60° or more and more preferably 70° or more because the disposition of the thick semiconductor device is limited.

The maximum angle of the inclined part of the insulating layer is measured as follows.

The three-dimensional shape of the insulating layer is measured using a laser microscope to obtain three-dimensional shape data of the insulating layer. Next, for the inclined part formed between the semiconductor device and the ground wiring line, an angle between the surface of the printed wiring board 10 and the inside of the inclined surface of the insulating layer is measured at nine points, and the largest angle among the nine angles is defined as a maximum angle.

The nine measurement points described above are basically random and vary depending on the shape of the insulating layer. However, for the measurement point, it is preferable that a point where a value of the height of the insulating layer is larger than a value of a distance corresponding to the above-described distance Xm (refer to FIG. 1) between the measurement point and the ground wiring line is included in the measurement point. In addition, since the inclination angle of the inclined part changes depending on the orientation of the inclination angle or the height of the peripheral member, the inclination angle is measured in a vertical direction with respect to the outer frame portion of the insulating layer at the measurement point, and the measurement is performed for a plurality of inclined parts instead of one inclined part. For the above-described measurement point of the inclination angle, the phrase “the inclination angle is measured in a vertical direction with respect to the outer frame portion of the insulating layer” means that the inclination angle is measured along the line Lm on the insulating layer 16 perpendicular to the outer frame portion of the insulating layer 16, that is, ground wiring line 12, for example, as shown in FIG. 2.

In a case of measuring the maximum angle of the inclined part of the insulating layer, the three-dimensional shape of the insulating layer is measured using a laser microscope, and a measurement magnification at this time is preferably 5/1 to 200/1 and more preferably 50/1 to 200/1.

The insulating layer is formed by jetting the insulating ink with an ink jet. The insulating layer is a cured film of the insulating ink. For example, the insulating layer is formed by applying the insulating ink and then irradiating the insulating ink with an active energy ray. The insulating ink will be described later.

Here, FIG. 18 is a schematic view showing another example of the configuration of the insulating layer of the printed circuit board according to the embodiment of the present invention. It should be noted that, in FIG. 18, the same configurations as the configurations shown in FIGS. 1 to 6 are designated by the same reference numerals, and the detailed description thereof will be omitted.

In FIG. 18, the ground wiring line 40 is disposed in a pentagonal shape on the surface 10a of the printed wiring board 10. Further, the ground wiring line 42 is disposed to be orthogonal to two sides of the ground wiring line 40 facing each other. The first region D₁ surrounded by the ground wiring line 40 is further divided into a second region D₂ and a third region D₃ by the ground wiring line 42. The semiconductor device 44, the electronic components 45a and 45b, the semiconductor device 46, and the electronic components 47a and 47b are mounted in the second region D₂. A semiconductor device 48 is mounted in the third region D₃.

In the mounting state of the semiconductor device shown in FIG. 18, the insulating layer 16 can be formed in the entire region of the first region D₁ including the second region D₂ and the third region D₃. In addition, the insulating layer 16 can also be formed in the second region D₂ and the third region D₃, respectively.

In a case of forming the insulating layer 16, three-dimensional shape data is acquired for each of the first region D₁, the second region D₂, and the third region D₃ to be formed to obtain slice data. The number of layers for forming the insulating layer 16 and the thickness of each layer in the direction Y are set for each of the first region D₁, the second region D₂, and the third region D₃ to be formed. The print image of the set number of layers is obtained from the slice data. Each layer is formed by jetting the insulating ink with an ink jet based on the print image representing each layer, and the insulating layer 16 is formed for each of the first region D₁, the second region D₂, and the third region D₃ to be formed. In this case, there is a case where the insulating layer 16 is formed in the first region D₁ including the second region D₂ and the third region D₃, and a case where the insulating layer 16 is formed for each of the second region D₂ and the third region D₃.

The thickness of the insulating layer is preferably in a range of 30 to 3000 μm. That is, it is preferable that the thinnest portion of the insulating layer is 30 μm or more and the thickest portion of the insulating layer is 3000 μm or less. In a case where the thickness of the insulating layer is within the above-described range, the conductive ink is easily formed, and the electromagnetic wave shielding properties of the electromagnetic wave shielding layer to be formed are improved.

In addition, the absolute value of the difference between the maximum value and the minimum value of the thickness of the insulating layer is preferably 30 μm or more, and more preferably 100 μm or more, but the upper limit value of the absolute value of the above-described difference is not particularly limited.

In a case where the absolute value of the difference between the maximum value and the minimum value of the thickness of the insulating layer is 30 μm or more, the uppermost surface of the insulating layer is easily smoothed. The electromagnetic wave shielding layer is easily and uniformly formed by the conductive ink, and the electromagnetic wave shielding properties are improved.

The thickness Tm (refer to FIG. 5) of the insulating layer is a thickness measured with reference to a surface of the printed wiring board in contact with the insulating layer or a surface of an electronic component such as a semiconductor device. The thickness of the insulating layer is a value obtained by acquiring a cross-sectional image of the insulating layer, measuring lengths of 10 points corresponding to the thickness of the insulating layer, and obtaining an average value of the lengths of the 10 points.

### (Electromagnetic Wave Shielding Layer)

The electromagnetic wave shielding layer shields electromagnetic waves so that the electromagnetic wave does not reach the semiconductor device embedded in the insulating layer from the outside. In addition, the electromagnetic wave shielding layer also shields electromagnetic waves radiated from a semiconductor device embedded in the insulating layer from being radiated to the outside. The electromagnetic wave shielding layer suppresses an influence of the electromagnetic interference from the outside on the semiconductor device, and suppresses an influence of the electromagnetic wave radiated from the semiconductor device on other semiconductor devices, electronic devices, or the like.

The electromagnetic wave shielding layer is electrically connected to the ground wiring line 12 as shown in FIG. 6, but in a case where at least a part of the electromagnetic wave shielding layer 18 is electrically connected to the ground wiring line 12, a current generated by the incidence of the electromagnetic wave on the electromagnetic wave shielding layer 18 flows to the ground, and the electromagnetic wave can be attenuated. The more the number of regions in which the electromagnetic wave shielding layer 18 and the ground wiring line 12 are electrically connected to each other, the more easily the current generated by the electromagnetic wave incident on the electromagnetic wave shielding layer 18 flows to the ground, and the more the electromagnetic wave can be further attenuated. In addition, since the portion where the ground wiring line 12 is consecutive is a portion where the electromagnetic wave passing through the portion where the ground wiring line 12 is not consecutive is reduced, the more the portion where the ground wiring line 12 is consecutive is, the more the electromagnetic wave can be attenuated. Therefore, for example, as shown in FIG. 6, it is preferable that there is a large number of regions in which the electromagnetic wave shielding layer 18 and the ground wiring line 12 are electrically connected to each other.

The electromagnetic wave shielding layer is formed by jetting a conductive ink by the ink jet onto the insulating layer. The electromagnetic wave shielding layer is a cured film of the conductive ink. The conductive ink will be described later.

A thickness of the electromagnetic wave shielding layer is preferably 0.1 μm to 100 μm, and more preferably 1 μm to 50 μm.

The thickness of the electromagnetic wave shielding layer is a value obtained by acquiring a cross-sectional image of the electromagnetic wave shielding layer, measuring lengths of 10 points corresponding to the thickness of the electromagnetic wave shielding layer, and obtaining an average value of the lengths of the 10 points.

### (Semiconductor Device)

The semiconductor device is not particularly limited, and the following are examples thereof.

The semiconductor device is not particularly limited, and examples thereof include logic large scale integration (LSI) (for example, an application specific integrated circuit (ASIC), a field programmable gate array (FPGA), and an application specific standard product (ASSP)), microprocessors (for example, a central processing unit (CPU) and a graphics processing unit (GPU)), memories (for example, a dynamic random access memory (DRAM), a hybrid memory cube (HMC), a magnetic RAM (MRAM), a phase-change memory (PCM), a resistive RAM (ReRAM), a ferroelectric RAM (FeRAM), and a flash memory (such as a Not AND (NAND) flash)), power devices, analog integrated circuits (IC) (for example, a direct current (DC)-direct current (DC) converter and an isolated gate bipolar transistor (IGBT)), A/D converters, micro electro mechanical systems (MEMS) (for example, an acceleration sensor, a pressure sensor, an oscillator, and a gyro sensor), power amplifiers, wireless (for example, a global positioning system (GPS), frequency modulation (FM), near field communication (NFC), an RF expansion module (RFEM), a monolithic microwave integrated circuit (MMIC), and a wireless local area network (WLAN)), discrete elements, back side illumination (BSI), contact image sensors (CIS), passive devices, bandpass filters, surface acoustic wave (SAW) filters, radio frequency (RF) filters, radio frequency integrated passive devices (RFIPD), broadband (BB), laminated capacitor, and quartz oscillator.

The semiconductor device may be a passive element or an active element, and the semiconductor device also includes a switch, a phase shifter, and the like in addition to the above description, and also includes an inductor and a balun transformer that converts or modulates a high-frequency signal.

For example, as shown in FIG. 11, the semiconductor device 14 has a side surface 14c perpendicular to the surface 10a of the printed wiring board 10, and a height H from the surface 10a of the printed wiring board 10 is 0.5 mm or more. In a case where the height H of the semiconductor device 14 is 0.5 mm or more, it is difficult to cause the insulating ink to adhere to the side surface of the semiconductor device 14, but according to the manufacturing method of a printed circuit board, it is possible to form an electromagnetic wave shielding layer having excellent coverage and excellent electromagnetic wave shielding characteristics.

In a case where the height H of the semiconductor device 14 is 3 mm or less, the distance between the ink jet head and the substrate surface is narrowed, so that the influence of the mist of the jetted ink or the bending of the ink is reduced. From this, in a printing of a layer having a height equal to the height of the substrate, the deterioration of the printing quality is suppressed, and the occurrence of the adhesion of the ink to an unintended portion, the occurrence of the ink leakage, and the deterioration of the short or the shield properties is suppressed, so that the height H of the semiconductor device 14 is preferably 3 mm or less.

The height H of the semiconductor device 14 is obtained by measuring a length from the surface 10a of the printed wiring board 10 to a point farthest from the surface 10a of the printed wiring board 10 of the semiconductor device 14 in a state where the semiconductor device 14 is mounted on the printed wiring board 10, using a microscope.

The shortest distance between the semiconductor device and the ground wiring line is, for example, 0.2 to 1.0 mm. In a case where the above-described shortest distance is 0.2 to 1.0 mm, it is difficult to cause the insulating ink to adhere to the side surface of the semiconductor device, but according to the manufacturing method of a printed circuit board, it is possible to form an insulating layer having an inclined part, and further to form an electromagnetic wave shielding layer having excellent coverage and excellent electromagnetic wave shielding characteristics.

In FIG. 1, the above-described shortest distance is obtained by measuring the distance between each side surface of the semiconductor device 14 and the ground wiring line 12 is measured in a state where the semiconductor device 14 is mounted on the printed wiring board 10 to set the shortest distance Xm in the measured distance as the shortest distance.

The distance between each side surface of the semiconductor device 14 and the ground wiring line 12 is measured using a microscope.

Hereinafter, the insulating ink and the conductive ink will be described.

### (Insulating Ink)

The insulating ink means an ink for forming an insulating layer having electrical insulating properties. The electrical insulating properties mean properties that a volume resistivity is 10¹⁰ Ωcm or more.

Hereinafter, the description common to the first insulating ink and the second insulating ink will be simply referred to as “insulating ink”.

The insulating ink is preferably an active energy ray curable-type ink.

It is preferable that the insulating ink contain a polymerizable monomer and a polymerization initiator.

### —Polymerizable Monomer—

The polymerizable monomer refers to a monomer having at least one polymerizable group in one molecule. The polymerizable group in the polymerizable monomer may be a cationically polymerizable group or a radically polymerizable group. From the viewpoint of curing properties, the polymerizable group is preferably a radically polymerizable group. In addition, from the viewpoint of curing properties, the radically polymerizable group is preferably an ethylenically unsaturated group.

The monomer refers to a compound having a molecular weight of 1,000 or less. The molecular weight can be calculated from the type and number of atoms constituting the compound.

The polymerizable monomer may be a monofunctional polymerizable monomer having one polymerizable group or a polyfunctional polymerizable monomer having two or more polymerizable groups.

The monofunctional polymerizable monomer is not particularly limited as long as it is a monomer having one polymerizable group.

From the viewpoint of curing properties, the monofunctional polymerizable monomer is preferably a monofunctional radically polymerizable monomer, and more preferably a monofunctional ethylenically unsaturated monomer.

Examples of the monofunctional ethylenically unsaturated monomer include monofunctional (meth)acrylate, monofunctional (meth)acrylamide, a monofunctional aromatic vinyl compound, monofunctional vinyl ether, and a monofunctional N-vinyl compound.

Examples of the monofunctional (meth)acrylate include methyl (meth)acrylate, ethyl (meth)acrylate, propyl (meth)acrylate, n-butyl (meth)acrylate, hexyl (meth)acrylate, 2-ethylhexyl (meth)acrylate, tert-octyl (meth)acrylate, isoamyl (meth)acrylate, decyl (meth)acrylate, isodecyl (meth)acrylate, lauryl (meth)acrylate, stearyl (meth)acrylate, and isostearyl (meth)acrylate, cyclohexyl (meth)acrylate, 4-n-butylcyclohexyl (meth)acrylate, 4-tert-butylcyclohexyl (meth)acrylate, bornyl (meth)acrylate, isobornyl (meth)acrylate, 2-ethylhexyldiglycol (meth)acrylate, butoxyethyl (meth)acrylate, 2-chloroethyl (meth)acrylate, 4-bromobutyl (meth)acrylate, cyanoethyl (meth)acrylate, benzyl (meth)acrylate, and butoxymethyl (meth)acrylate, 3-methoxybutyl (meth)acrylate, 2-(2-methoxyethoxy) ethyl (meth)acrylate, 2-(2-butoxyethoxy) ethyl (meth)acrylate, 2,2,2-tetrafluorocthyl (meth)acrylate, 1H,1H,2H,2H-perfluorodecyl (meth)acrylate, 4-butylphenyl (meth)acrylate, phenyl (meth)acrylate, 2,4,5-tetramethylphenyl (meth)acrylate, 4-chlorophenyl (meth)acrylate, 2-phenoxymethyl (meth)acrylate,2-phenoxyethyl (meth)acrylate, glycidyl (meth)acrylate, glycidyloxybutyl (meth)acrylate, glycidyloxyethyl (meth)acrylate, glycidyloxypropyl (meth)acrylate, tetrahydrofurfuryl (meth)acrylate, 2-hydroxyethyl (meth)acrylate, 3-hydroxypropyl (meth)acrylate, 2-hydroxypropyl (meth)acrylate, 2-hydroxybutyl (meth)acrylate, 3-hydroxybutyl (meth)acrylate, 4-hydroxybutyl (meth)acrylate, cyclic trimethylolpropane formal (meth)acrylate, phenylglycidyl ether (meth)acrylate, dimethylaminoethyl (meth)acrylate, diethylaminoethyl (meth)acrylate, dimethylaminopropyl (meth)acrylate, diethylaminopropyl (meth)acrylate, trimethoxysilylpropyl (meth)acrylate, trimethylsilylpropyl (meth)acrylate, polyethylene oxide monomethyl ether (meth)acrylate, polyethylene oxide (meth)acrylate, polyethylene oxide monoalkyl ether (meth)acrylate, dipropylene glycol (meth)acrylate, polypropylene oxide monoalkyl ether (meth)acrylate, 2-methacryloyloxyethyl succinate, 2-methacryloyloxyhexahydrophthalic acid,2-methacryloyloxycthyl-2-hydroxypropyl phthalate, ethoxydiethylene glycol (meth)acrylate, butoxydiethylene glycol (meth)acrylate, trifluoroethyl (meth)acrylate, perfluorooctylethyl (meth)acrylate, 2-hydroxy-3-phenoxypropyl (meth)acrylate, ethylene oxide (EO)-modified phenol (meth)acrylate, EO-modified cresol (meth)acrylate, EO-modified nonylphenol (meth)acrylate, propyleneoxide (PO)-modified nonylphenol (meth)acrylate, EO-modified-2-ethylhexyl (meth)acrylate, dicyclopentenyl (meth)acrylate, dicyclopentenyloxyethyl (meth)acrylate, dicyclopentanyl (meth)acrylate, (3-ethyl-3-oxctanylmethyl) (meth)acrylate, phenoxyethylene glycol (meth)acrylate, 2-carboxyethyl (meth)acrylate, and 2-(meth)acryloyloxyethyl succinate.

Among these, from the viewpoint of improving heat resistance, the monofunctional (meth)acrylate is preferably a monofunctional (meth)acrylate having an aromatic ring or an aliphatic ring, and is more preferably isobornyl (meth)acrylate, 4-tert-butylcyclohexyl (meth)acrylate, dicyclopentenyl (meth)acrylate, or dicyclopentanyl (meth)acrylate.

Examples of the monofunctional (meth)acrylamide include (meth)acrylamide, N-methyl (meth)acrylamide, N-ethyl (meth)acrylamide, N-propyl (meth)acrylamide, N-n-butyl (meth)acrylamide, N-t-butyl (meth)acrylamide, N-butoxymethyl (meth)acrylamide, N-isopropyl (meth)acrylamide, N-methylol (meth)acrylamide, N,N-dimethyl (meth)acrylamide, N,N-diethyl (meth)acrylamide, and (meth)acryloylmorpholine.

Examples of the monofunctional aromatic vinyl compound include styrene, dimethylstyrene, trimethylstyrene, isopropylstyrene, chloromethylstyrene, methoxystyrene, acetoxystyrene, chlorostyrene, dichlorostyrene, bromostyrene, vinyl benzoic acid methyl ester, 3-methylstyrene, 4-methylstyrene, 3-ethylstyrene, 4-ethylstyrene, 3-propylstyrene, 4-propylstyrene, 3-butylstyrene, 4-butylstyrene, 3-hexylstyrene, 4-hexylstyrene, 3-octylstyrene, 4-octylstyrene, 3-(2-ethylhexyl) styrene, 4-(2-ethylhexyl) styrene, allyl styrene, isopropenyl styrene, butenyl styrene, octenyl styrene, 4-t-butoxycarbonyl styrene, and 4-t-butoxystyrene.

Examples of the monofunctional vinyl ether include methyl vinyl ether, ethyl vinyl ether, propyl vinyl ether, n-butyl vinyl ether, t-butyl vinyl ether, 2-ethylhexyl vinyl ether, n-nonyl vinyl ether, lauryl vinyl ether, cyclohexyl vinyl ether, cyclohexyl methyl vinyl ether, 4-methylcyclohexyl methyl vinyl ether, benzyl vinyl ether, dicyclopentenyl vinyl ether, 2-dicyclopentenoxyethyl vinyl ether, methoxyethyl vinyl ether, ethoxyethyl vinyl ether, butoxyethyl vinyl ether, methoxyethoxyethyl vinyl ether, ethoxyethoxyethyl vinyl ether, methoxypolyethylene glycol vinyl ether, tetrahydrofurfuryl vinyl ether,2-hydroxyethyl vinyl ether, 2-hydroxypropyl vinyl ether, ether, 4-hydroxybutyl vinyl 4-hydroxymethylcyclohexylmethyl vinyl ether, diethylene glycol monovinyl ether, polyethylene glycol vinyl ether, chloroethyl vinyl ether, chlorobutyl vinyl ether, chloroethoxyethyl vinyl ether, phenylethyl vinyl ether, and phenoxypolyethylene glycol vinyl ether.

Examples of the monofunctional N-vinyl compound include N-vinyl-ε-caprolactam and N-vinylpyrrolidone.

The polyfunctional polymerizable monomer is not particularly limited as long as it is a monomer having two or more polymerizable groups. From the viewpoint of curing properties, the polyfunctional polymerizable monomer is preferably a polyfunctional radically polymerizable monomer, and more preferably a polyfunctional ethylenically unsaturated monomer.

Examples of the polyfunctional ethylenically unsaturated monomer include a polyfunctional (meth)acrylate compound and a polyfunctional vinyl ether.

Examples of the polyfunctional (meth)acrylate include ethylene glycol di(meth)acrylate, diethylene glycol di(meth)acrylate, triethylene glycol di(meth)acrylate, polyethylene glycol di(meth)acrylate, propylene glycol di(meth)acrylate, dipropylene glycol di(meth)acrylate, tripropylene glycol di(meth)acrylate, polypropylene glycol di(meth)acrylate,butylene glycol di(meth)acrylate, tetraethylene glycol di(meth)acrylate, neopentyl glycol di(meth)acrylate, 3-methyl-1,5-pentanediol di(meth)acrylate, 1,4-butanediol di(meth)acrylate, 1,6-hexanediol di(meth)acrylate, heptanediol di(meth)acrylate, EO-modified neopentyl glycol di(meth)acrylate, PO-modified neopentyl glycol di(meth)acrylate,EO-modified hexanediol di(meth)acrylate, PO-modified hexanediol di(meth)acrylate, octanediol di(meth)acrylate, nonanediol di(meth)acrylate, decanediol di(meth)acrylate, dodecanediol di(meth)acrylate, glycerin di(meth)acrylate, pentacrythritol di(meth)acrylate, cthylene glycol diglycidyl ether di(meth)acrylate, diethylene glycol diglycidyl ether di(meth)acrylate, tricyclodecane dimethanol di(meth)acrylate, trimethylolethane tri (meth)acrylate, trimethylolpropane tri (meth)acrylate, trimethylolpropane EO-added tri (meth)acrylate, pentacrythritol tri (meth)acrylate, pentaerythritol tetra(meth)acrylate, dipentaerythritol tetra(meth)acrylate,dipentaerythritol penta (meth)acrylate, dipentaerythritol hexa (meth)acrylate, tri (meth)acryloyloxyethoxytrimethylolpropane, glycerin polyglycidyl ether poly (meth)acrylate, and tris (2-acryloyloxyethyl) isocyanurate.

Examples of the polyfunctional vinyl ether include 1,4-butanediol divinyl ether, ethylene glycol divinyl ether, diethylene glycol divinyl ether, triethylene glycol divinyl ether, polyethylene glycol divinyl ether, propylene glycol divinyl ether, butylene glycol divinyl ether, hexanediol divinyl ether, 1,4-cyclohexanedimethanol divinyl ether,bisphenol A alkylene oxide divinyl ether, bisphenol F alkylene oxide divinyl ether, trimethylolethane trivinyl ether, trimethylolpropane trivinyl ether, ditrimethylolpropane tetravinyl ether, glycerin trivinyl ether, pentaerythritol tetravinyl ether, dipentaerythritol pentavinyl ether, dipentaerythritol hexavinyl ether, EO-added trimethylolpropane trivinyl ether, PO-added trimethylolpropane trivinyl ether, EO-added ditrimethylolpropane tetravinyl ether, PO-added ditrimethylolpropane tetravinyl ether, EO-added pentaerythritol tetravinyl ether, PO-added pentaerythritol tetravinyl ether, EO-added dipentaerythritol hexavinyl ether, and PO-added dipentaerythritol hexavinyl ether.

Among these, from the viewpoint of curing properties, the polyfunctional polymerizable monomer is preferably a monomer having 3 to 11 carbon atoms in a portion other than a (meth)acryloyl group. As the monomer having 3 to 11 carbon atoms in a portion other than a (meth)acryloyl group, specifically, 1,6-hexanediol di(meth)acrylate, dipropylene glycol di(meth)acrylate, PO-modified neopentyl glycol di(meth)acrylate, 1,4-butanediol di(meth)acrylate, 3-methyl-1,5-pentanediol di(meth)acrylate, polyethylene glycol di(meth)acrylate (EO chain n=4), or 1,10-decanediol di(meth)acrylate is more preferable.

The content of the polymerizable monomer with respect to the total mass of the insulating ink is preferably 10% by mass to 98% by mass, and more preferably 50% by mass to 98% by mass.

### —Polymerization Initiator—

Examples of the polymerization initiator contained in the insulating ink include an oxime compound, an alkylphenone compound, an acylphosphine compound, an aromatic onium salt compound, an organic peroxide, a thio compound, a hexaarylbisimidazole compound, a borate compound, an azinium compound, a titanocene compound, an active ester compound, a carbon halogen bond-containing compound, and an alkylamine.

Particularly, from the viewpoint of further improving conductivity, the polymerization initiator contained in the insulating ink is preferably at least one compound selected from the group consisting of an oxime compound, an alkylphenone compound, and a titanocene compound, more preferably an alkylphenone compound, and even more preferably at least one compound selected from the group consisting of an α-aminoalkylphenone compound and a benzyl ketal alkylphenone.

The content of the polymerization initiator with respect to the total mass of the insulating ink is preferably 0.5% by mass to 20% by mass, and more preferably 2% by mass to 10% by mass.

The insulating ink may contain a component other than the polymerization initiator and the polymerizable monomer. Examples of the other components include a chain transfer agent, a polymerization inhibitor, a sensitizer, a surfactant, and an additive.

### —Chain Transfer Agent—

The insulating ink may contain at least one chain transfer agent.

From the viewpoint of improving reactivity of photopolymerization reaction, the chain transfer agent is preferably a polyfunctional thiol.

Examples of the polyfunctional thiol include aliphatic thiols such as hexane-1,6-dithiol, decane-1,10-dithiol, dimercaptodiethyl ether, and dimercaptodiethyl sulfide, aromatic thiols such as xylylene dimercaptan, 4,4′-dimercaptodiphenylsulfide, and 1,4-benzenedithiol;
poly (mercaptoacetate) of a polyhydric alcohol such as ethylene glycol bis (mercaptoacetate), polyethylene glycol bis (mercaptoacetate), propylene glycol bis (mercaptoacetate), glycerin tris (mercaptoacetate), trimethylolethane tris (mercaptoacetate), trimethylolpropane tris (mercaptoacetate), pentaerythritol tetrakis (mercaptoacetate), and dipentaerythritol hexakis (mercaptoacetate);
ethylene glycol bis (3-mercaptopropionate), polyethylene glycol bis (3-mercaptopropionate), propylene glycol bis (3-mercaptopropionate), glycerin tris (3-mercaptopropionate), trimethylolethane tris (mercaptopropionate), trimethylolpropane tris (3-mercaptopropionate),poly (3-mercaptopropionate) of a polyhydric alcohol such as pentaerythritol tetrakis (3-mercaptopropionate) and dipentaerythritol hexakis (3-mercaptopropionate); and poly (mercaptobutyrate) such as 1,4-bis (3-mercaptobutyryloxy) butane, 1,3,5-tris (3-mercaptobutyloxyethyl)-1,3,5-triazine-2,4,6 (1H,3H,5H)-trione, and pentaerythritol tetrakis (3-mercaptobutyrate).

### —Polymerization Inhibitor—

The insulating ink may contain at least one polymerization inhibitor.

Examples of the polymerization inhibitor include p-methoxyphenol, quinones (for example, hydroquinone, benzoquinone, and methoxybenzoquinone), phenothiazine, catechols, alkylphenols (for example, dibutyl hydroxy toluene (BHT)), alkyl bisphenols, zinc dimethyldithiocarbamate, copper dimethyldithiocarbamate, copper dibutyldithiocarbamate, copper salicylate, thiodipropionic acid esters, mercaptobenzimidazole, phosphites, 2,2,6,6-tetramethylpiperidine-1-oxyl (TEMPO), 2,2,6,6-tetramethyl-4-hydroxypiperidine-1-oxyl (TEMPOL), and tris (N-nitroso-N-phenylhydroxylamine) aluminum salt (also known as Cupferron Al).

Among these, as the polymerization inhibitor, at least one selected from p-methoxyphenol, catechols, quinones, alkylphenols, TEMPO, TEMPOL, or tris (N-nitroso-N-phenylhydroxylamine) aluminum salt is preferable, and at least one selected from p-methoxyphenol, hydroquinone, benzoquinone, BHT, TEMPO, TEMPOL, or tris (N-nitroso-N-phenylhydroxylamine) aluminum salt is more preferable.

In a case where the ink contains a polymerization inhibitor, a content of the polymerization inhibitor is preferably 0.01% by mass to 2.0% by mass, more preferably 0.02% by mass to 1.0% by mass, and still more preferably 0.03% by mass to 0.5% by mass with respect to the total mass of the ink.

### —Sensitizer—

The insulating ink may contain at least one sensitizer.

Examples of the sensitizer include a polynuclear aromatic compound (for example, pyrene, perylene, triphenylene, and 2-ethyl-9,10-dimethoxyanthracene), a xanthene-based compound (for example, fluorescein, eosin, erythrosin, rhodamine B, and rose bengal), a cyanine-based compound (for example, thiacarbocyanine and oxacarbocyanine), a merocyanine-based compound (for example, merocyanine and carbomerocyanine), a thiazine-based compound (for example, thionine,methylene blue and toluidine blue), an acridine-based compound (for example, acridine orange, chloroflavine, and acryflavine), an anthraquinone-based compound (for example, anthraquinone), a squarylium-based compound (for example, squarylium), a coumarin-based compound (for example, 7-diethylamino-4-methylcoumarin), a thioxanthone-based compound (for example, isopropylthioxanthone), and a thiochromanone-based compound (for example, thiochromanone). Among these, the sensitizer is preferably a thioxanthone-based compound.

In a case where the insulating ink contains a sensitizer, the content of the sensitizer is not particularly limited, but is preferably 1.0% by mass to 15.0% by mass and more preferably 1.5% by mass to 5.0% by mass with respect to the total mass of the insulating ink.

### —Surfactant—

The insulating ink may contain at least one surfactant.

Examples of the surfactant include surfactants described in JP1987-173463A (JP-S62-173463A) and JP1987-183457A (JP-S62-183457A). In addition, examples of the surfactant include anionic surfactants such as dialkyl sulfosuccinate, alkyl naphthalene sulfonate, and a fatty acid salt; nonionic surfactants such as polyoxyethylene alkyl ether, polyoxyethylene alkyl allyl ether, acetylene glycol, and a polyoxyethylene-polyoxypropylene block copolymer; and cationic surfactants such as an alkylamine salt and a quaternary ammonium salt. In addition, the surfactant may be a fluorine-based surfactant or a silicone-based surfactant.

In a case where the insulating ink contains a surfactant, the content of the surfactant with respect to the total mass of the insulating ink is preferably 0.5% by mass or less, and more preferably 0.1% by mass or less. A lower limit value of the content of the surfactant is not particularly limited.

In a case where the content of the surfactant is 0.5% by mass or less, the insulating ink is unlikely to spread after the application of the insulating ink. Therefore, the outflow of the insulating ink is suppressed, and the electromagnetic wave shielding properties are improved.

### —Organic Solvent—

The insulating ink may contain at least one organic solvent.

Examples of the organic solvent include (poly) alkylene glycol monoalkyl ethers such as ethylene glycol monoethyl ether, diethylene glycol monoethyl ether, triethylene glycol monomethyl ether, propylene glycol monomethyl ether (PGME), dipropylene glycol monomethyl ether, and tripropylene glycol monomethyl ether;
(poly) alkylene glycol dialkyl ethers such as ethylene glycol dibutyl ether, diethylene glycol dimethyl ether, diethylene glycol diethyl ether, dipropylene glycol diethyl ether, and tetraethylene glycol dimethyl ether;
(poly) alkylene glycol acetates such as diethylene glycol acetate;
(poly) alkylene glycol diacetates such as ethylene glycol diacetate and propylene glycol diacetate;
(poly) alkylene glycol monoalkyl ether acetates such as ethylene glycol monobutyl ether acetate and propylene glycol monomethyl ether acetate, ketones such as methyl ethyl ketone and cyclohexanone;
lactones such as γ-butyrolactone;
esters such as ethyl acetate, propyl acetate, butyl acetate, 3-methoxybutyl acetate (MBA), methyl propionate, and ethyl propionate;
cyclic ethers such as tetrahydrofuran and dioxane; and
amides such as dimethylformamide and dimethylacetamide.

In a case where the insulating ink contains an organic solvent, the content of the organic solvent with respect to the total mass of the insulating ink is preferably 70% by mass or less, and more preferably 50% by mass or less. A lower limit value of the content of the organic solvent is not particularly limited.

### —Additive—

As necessary, the insulating ink may contain additives such as a co-sensitizer, an ultraviolet absorber, an antioxidant, an antifading agent, and a basic compound.

### —Physical Properties—

From the viewpoint of improving jetting stability in a case where the insulating ink is applied using an ink jet recording method, the pH (hydrogen ion concentration) of the insulating ink is preferably 7 to 10, and more preferably 7.5 to 9.5. The pH is measured at 25° C. using a pH meter, such as a pH meter (model number “HM-31”) manufactured by DKK-Toa Corporation.

The viscosity of the insulating ink is preferably 0.5 mPa·s to 60 mPa·s, and more preferably 2 mPa·s to 40 mPa·s. The viscosity is measured at 25° C. using a viscometer, such as a TV-22 type viscometer manufactured by Toki Sangyo Co., Ltd.

The surface tension of the insulating ink is preferably 60 mN/m or less, more preferably 20 mN/m to 50 mN/m, and even more preferably 25 mN/m to 45 mN/m. The surface tension is measured at 25° C. using a surface tension meter, for example, by a plate method using an automatic surface tension meter (trade name, “CBVP-Z”) manufactured by Kyowa Interface Science Co., Ltd.

### (Application of Insulating Ink)

The insulating ink is applied with an ink jet recording method. In the ink jet recording method, a small amount of the insulating ink is jetted, so that a thickness of the insulating layer formed by one application can be reduced. In addition, in the ink jet recording method, a film having an optional thickness can be formed by further performing printing on a printed material after printing and stacking a plurality of layers.

The ink jet recording method may be any of an electric charge control method of jetting an ink by using electrostatic attraction force, a drop-on-demand method (pressure pulse method) using a vibration pressure of a piezo element, an acoustic ink jet method of jetting an ink by using a radiation pressure by means of converting electric signals into acoustic beams and irradiating the ink with the acoustic beams, or a thermal ink jet (Bubble Jet (registered trademark)) method of forming air bubbles by heating an ink and using the generated pressure.

As the ink jet recording method, particularly, an ink jet recording method, disclosed in JP1979-059936A (JP-S54-059936A), of jetting an ink from a nozzle using an action force caused by a rapid change in volume of the ink after being subjected to an action of thermal energy can be effectively used.

Regarding the ink jet recording method, the method disclosed in paragraphs 0093 to 0105 of JP2003-306623A can also be referred to.

Examples of ink jet heads used in the ink jet recording method are not particularly limited, but include ink jet heads for a shuttle scan method of performing recording while scanning the heads in a width direction of the electronic substrate using short serial heads and a line method using line heads each of which is formed of recording elements arranged for the entire region of one side of the electronic substrate.

The amount of droplets of the insulating ink jetted from the ink jet head is preferably 1 pL (picoliter) to 100 pL, more preferably 3 pL to 80 pL, and still more preferably 3 pL to 20 pL.

### (Formation of Insulating Layer)

In a case where the insulating layer is formed, it is preferable to apply the insulating ink and then irradiate the insulating ink with an active energy ray. Particularly, it is preferable that the step such as application of the insulating ink and irradiation of the insulating ink with the active energy ray is repeated.

Examples of the active energy ray include ultraviolet rays, visible rays, and electron beams. Among these, ultraviolet rays (hereinafter, also referred to as “UV”) are preferable.

A peak wavelength of the ultraviolet rays is preferably 200 nm to 405 nm, more preferably 250 nm to 400 nm, and still more preferably 300 nm to 400 nm.

From the viewpoint of further suppressing the occurrence of wrinkles in the insulating layer, the illuminance during the irradiation with the active energy ray is more preferably 2 W/cm² or more, and still more preferably 4 W/cm² or more. An upper limit value of the illuminance is not particularly limited, but is, for example, 20 W/cm².

An exposure time in the semi-curing treatment and the curing step is preferably 0.1 seconds or longer, and from the viewpoint that the effect of the embodiment of the present invention is more excellent, it is more preferably 0.5 seconds or longer. The upper limit may be 30 seconds or less, but is preferably 10 seconds or less.

An exposure amount during the irradiation with active energy ray is preferably 100 mJ/cm² to 10,000 mJ/cm², and more preferably 500 mJ/cm² to 7,500 mJ/cm². Note that in a case where the application of the insulating ink and the irradiation with the active energy ray are defined as one cycle, the exposure amount mentioned herein means the exposure amount of the active energy ray in one cycle.

As a light source for ultraviolet irradiation, a mercury lamp, a gas laser, and a solid-state laser are mainly used, and a mercury lamp, a metal halide lamp, and an ultraviolet fluorescent lamp are widely known.

In addition, a light emitting diode (UV-LED) and a laser diode (UV-LD) are compact, long-life, highly efficient, and low-cost, and are expected to be used as the light source for ultraviolet irradiation. Among these, the light source for ultraviolet irradiation is preferably a metal halide lamp, a high-pressure mercury lamp, a medium-pressure mercury lamp, a low-pressure mercury lamp, or UV-LED.

### (Conductive Ink)

The conductive ink means an ink for forming an electromagnetic wave shielding layer.

The conductive ink is preferably an ink containing metal particles (hereinafter, also called “metal particle ink”), an ink containing a metal complex (hereinafter, also called “metal complex ink”), or an ink containing a metal salt (hereinafter, also called “metal salt ink”), and more preferably a metal salt ink or a metal complex ink.

From the viewpoint of improving the electromagnetic wave shielding properties, the conductive ink is preferably an ink containing silver, and more preferably an ink containing a silver salt or an ink containing a silver complex.

### <<Metal Particle Ink>>

The metal particle ink is, for example, an ink composition obtained by dispersing metal particles in a dispersion medium.

### —Metal Particles—

Examples of the metal constituting the metal particles include base metal and noble metal particles. Examples of the base metal include nickel, titanium, cobalt, copper, chromium, manganese, iron, zirconium, tin, tungsten, molybdenum, and vanadium. Examples of the noble metal include gold, silver, platinum, palladium, iridium, osmium, ruthenium, rhodium, rhenium, and alloys containing these metals. Among these, from the viewpoint of the conductivity, the metal constituting the metal particles preferably includes at least one selected from the group consisting of silver, gold, platinum, nickel, palladium, and copper, and more preferably includes silver.

An average particle diameter of the metal particles is not particularly limited, but is preferably 10 nm to 500 nm, and more preferably 10 nm to 200 nm. In a case in which the average particle diameter is in the above range, a baking temperature of the metal particles is lowered, which improves process suitability for producing the electromagnetic wave shielding layer. Particularly, in a case where the metal particle ink is applied with an ink jet recording method, jettability is improved, which tends to improve pattern forming properties and film thickness uniformity of the electromagnetic wave shielding layer. The average particle diameter mentioned herein means an average value of primary particle diameters of the metal particles (average primary particle diameter).

The average particle diameter of the metal particles is measured by a laser diffraction/scattering method. The average particle diameter of the metal particles is, for example, a value obtained by measuring a 50% cumulative volume-based diameter (D₅₀) three times and calculating an average value of the value measured three times, and can be measured using a laser diffraction/scattering-type particle size distribution analyzer (trade name “LA-960” manufactured by Horiba, Ltd.).

In addition, the metal particle ink may contain metal particles having an average particle diameter of 500 nm or more, as necessary. In a case in which the metal particle ink contains metal particles having an average particle diameter of 500 nm or more, a melting point around the nm-sized metal particles is lowered around the μm-sized metal particles, which makes it possible to bond the metal particles to each other.

The content of the metal particles in the metal particle ink is preferably 10% by mass to 90% by mass, and more preferably 20% by mass to 50% by mass, with respect to the total mass of the metal particle ink. In a case where the content of the metal particles is 10% by mass or more, a surface resistivity of the electromagnetic wave shielding layer is further reduced. In a case in which the content of the metal particles is 90% by mass or less, jettability is improved in a case in which the metal particle ink is applied with an ink jet recording method.

In addition to the metal particles, the metal particle ink may contain, for example, a dispersing agent, a resin, a dispersion medium, a thickener, and a surface tension adjuster.

### —Dispersing Agent—

The metal particle ink may contain a dispersing agent that adheres to at least a part of a surface of the metal particles. The dispersing agent substantially constitutes metal colloidal particles, together with the metal particles. The dispersing agent has an action of covering the metal particles to improve dispersibility of the metal particles and prevent aggregation. The dispersing agent is preferably an organic compound capable of forming the metal colloidal particles. From the viewpoint of conductivity and dispersion stability, the dispersing agent is preferably an amine, a carboxylic acid or the salt thereof, an alcohol, or a resin dispersing agent.

The metal particle ink may contain one dispersing agent or two or more dispersing agents.

Examples of the amine include an aliphatic amine and an aromatic amine.

The aliphatic amine may be saturated or unsaturated. Among these, the aliphatic amine is preferably an aliphatic amine having 4 to 8 carbon atoms. The aliphatic amine having 4 to 8 carbon atoms may be linear or branched, or may have a ring structure.

Examples of the aliphatic amine include butylamine, normal pentylamine, isopentylamine, hexylamine, 2-ethylhexylamine, and octylamine.

Examples of the amine having an alicyclic structure include cycloalkylamines such as cyclopentylamine and cyclohexylamine.

Examples of an aromatic amine include aniline.

The amine may have a functional group other than an amino group. Examples of the functional group other than an amino group include a hydroxy group, a carboxy group, an alkoxy group, a carbonyl group, an ester group, and a mercapto group.

Examples of the carboxylic acid include formic acid, oxalic acid, acetic acid, hexanoic acid, acrylic acid, octylic acid, oleic acid, tianshic acid, ricinoleic acid, gallic acid, and salicylic acid.

Examples of the carboxylate include a metal salt of a carboxylic acid. The metal salt of the carboxylic acid may be formed of one metal ion or two or more metal ions.

The carboxylic acid and the carboxylate may have a functional group other than the carboxy group. Examples of the functional group other than the carboxy group include an amino group, a hydroxy group, an alkoxy group, a carbonyl group, an ester group, and a mercapto group.

Examples of the alcohol include a terpene-based alcohol, an allyl alcohol, and an oleyl alcohol. The alcohol is likely to be coordinated with the surface of the metal particles, and can suppress the aggregation of the metal particles.

Examples of the resin dispersing agent include a dispersing agent that has a nonionic group as a hydrophilic group and can be uniformly dissolved in a solvent. Examples of the resin dispersing agent include polyvinylpyrrolidone, polyethylene glycol, a polyethylene glycol-polypropylene glycol copolymer, polyvinyl alcohol, polyallylamine, and a polyvinyl alcohol-polyvinyl acetate copolymer.

The resin dispersing agent is preferably 1,000 to 50,000, and more preferably 1,000 to 30,000, in terms of a weight-average molecular weight.

The content of the dispersing agent in the metal particle ink is preferably 0.5% by mass to 50% by mass, and more preferably 1% by mass to 30% by mass, with respect to the total mass of the metal particle ink.

### —Dispersion Medium—

The metal particle ink preferably contains a dispersion medium. A type of the dispersion medium is not particularly limited, and examples thereof include a hydrocarbon, an alcohol, and water.

The metal particle ink may contain one dispersion medium or two or more dispersion media.

The dispersion medium contained in the metal particle ink is preferably volatile. A boiling point of the dispersion medium is preferably 50° C. to 250° C., more preferably 70° C. to 220° C., and still more preferably 80° C. to 200° C. In a case in which the boiling point of the dispersion medium is 50° C. to 250° C., the stability and baking properties of the metal particle ink tend to be simultaneously achieved.

In the present specification, the boiling point means a standard boiling point unless otherwise specified.

Examples of the hydrocarbon include an aliphatic hydrocarbon and an aromatic hydrocarbon.

Examples of the aliphatic hydrocarbon include a saturated or unsaturated aliphatic hydrocarbon such as tetradecane, octadecane, heptamethylnonane, tetramethylpentadecane, hexane, heptane, octane, nonane, decane, tridecane, methylpentane, normal paraffin, and isoparaffin.

Examples of the aromatic hydrocarbon include toluene and xylene.

Examples of the alcohol include an aliphatic alcohol and an alicyclic alcohol. In a case in which an alcohol is used as the dispersion medium, the dispersing agent is preferably an amine or a carboxylic acid or the salt thereof.

Examples of the aliphatic alcohol include a saturated or unsaturated aliphatic alcohol having 6 to 20 carbon atoms that may contain an ether bond in a chain, such as heptanol, octanol (for example, 1-octanol, 2-octanol, or 3-octanol), decanol (for example, 1-decanol), lauryl alcohol, tetradecyl alcohol, cetyl alcohol, 2-ethyl-1-hexanol, octadecyl alcohol, hexadecenol, and oleyl alcohol.

Examples of the alicyclic alcohol include a cycloalkanol such as cyclohexanol; a terpene alcohol such as terpineol (including α, β, and γ isomers, or any mixture of these) or dihydroterpineol; myrtenol, sobrerol, menthol, carveol, perillyl alcohol, pinocarveol, sobrerol, and verbenol.

The dispersion medium may be water. From the viewpoint of adjusting physical properties such as viscosity, surface tension, and volatility, the dispersion medium may be a mixed solvent of water and another solvent.

Another solvent to be mixed with water is preferably an alcohol or a glycol ether. The alcohol and the glycol ether used together with water is preferably an alcohol or a glycol ether that is miscible with water and has a boiling point of 130° C. or lower.

Specific examples of the alcohol include 1-propanol, 2-propanol, 1-butanol, 2-butanol, tert-butanol, and 1-pentanol.

Specific examples of the glycol ether include ethylene glycol monomethyl ether, ethylene glycol monoethyl ether, ethylene glycol monopropyl ether, and propylene glycol monomethyl ether.

A content of the dispersion medium in the metal particle ink is preferably 1% to 50% by mass, more preferably 10% to 45% by mass, and still more preferably 20% to 40% by mass with respect to the total mass of the metal particle ink. In a case where the content of the dispersion medium is 1% to 50% by mass, sufficient conductivity can be obtained as the conductive ink.

### —Resin—

The metal particle ink may contain a resin. Examples of the resin include polyester, polyurethane, a melamine resin, an acrylic resin, a styrene-based resin, a polyether, and a terpene resin.

The metal particle ink may contain one resin or two or more resins.

The content of the resin in the metal particle ink is preferably 0.1% by mass to 5% by mass with respect to the total mass of the metal particle ink.

### —Thickener—

The metal particle ink may contain a thickener. Examples of the thickener include clay minerals such as clay, bentonite, and hectorite; cellulose derivatives such as methyl cellulose, carboxymethyl cellulose, hydroxyethyl cellulose, hydroxypropyl cellulose, and hydroxypropyl methyl cellulose; and polysaccharides such as xanthan gum and guar gum.

The metal particle ink may contain one thickener or two or more thickeners.

The content of the thickener in the metal particle ink is preferably 0.1% by mass to 5% by mass with respect to the total mass of the metal particle ink.

### —Surfactant—

The metal particle ink may contain a surfactant. In a case in which the metal particle ink contains a surfactant, a uniform electromagnetic wave shielding layer is likely to be formed.

The surfactant may be any of an anionic surfactant, a cationic surfactant, or a nonionic surfactant. Among these, the surfactant is preferably a fluorine-based surfactant from the viewpoint of being able to adjust the surface tension with a small amount of content. In addition, the surfactant is preferably a compound having a boiling point higher than 250° C.

### —Physical Properties of Metal Particle Ink—

A viscosity of the metal particle ink is preferably 1 mPa·s to 100 mPa·s, more preferably 2 mPa·s to 50 mPa·s, and still more preferably 3 mPa·s to 30 mPa·s.

The viscosity of the metal particle ink is a value measured at 25° C. using a viscometer. The viscosity is measured using, for example, a VISCOMETER TV-22 type viscometer (manufactured by Toki Sangyo Co., Ltd.).

The surface tension of the metal particle ink is not particularly limited, and is preferably 20 mN/m to 45 mN/m and more preferably 25 mN/m to 40 mN/m.

The surface tension is a value measured at 25° C. using a surface tension meter.

The surface tension of the metal particle ink is measured using, for example, DY-700 (manufactured by Kyowa Interface Science Co., Ltd.).

### —Manufacturing Method of Metal Particles—

The metal particles may be a commercially available product or may be manufactured by a known method. Examples of a manufacturing method of the metal particles include a wet reduction method, a vapor phase method, and a plasma method. Preferred examples of the manufacturing method of the metal particles include a wet reduction method capable of manufacturing metal particles having an average particle diameter of 200 nm or less and having a narrow particle size distribution. Examples of the manufacturing method of the metal particles by a wet reduction method include the method described in JP2017-37761A, WO2014-57633A, and the like, the method including a step of mixing a metal salt with a reducing agent to obtain a complexing reaction solution; and a step of heating the complexing reaction solution to reduce metal ions in the complexing reaction solution and to obtain a slurry of metal nanoparticles.

In manufacturing the metal particle ink, a heat treatment may be performed such that the content of each component contained in the metal particle ink is adjusted to be in a predetermined range. The heat treatment may be performed under reduced pressure or under normal pressure. In a case where the heat treatment is performed under normal pressure, the heat treatment may be performed in the atmospheric air or in an inert gas atmosphere.

### <<Metal Complex Ink>>

The metal complex ink is, for example, an ink composition obtained by dissolving a metal complex in a solvent.

### —Metal Complex—

Examples of metals constituting the metal complex include silver, copper, gold, aluminum, magnesium, tungsten, molybdenum, zinc, nickel, iron, platinum, tin, and lead. Among these, from the viewpoint of conductivity, the metal constituting the metal complex preferably includes at least one selected from the group consisting of silver, gold, platinum, nickel, palladium, and copper, and more preferably includes silver.

The content of the metal contained in the metal complex ink is preferably 1% by mass to 40% by mass, more preferably 5% by mass to 30% by mass, and still more preferably 7% by mass to 20% by mass, with respect to the total mass of the metal complex ink, in terms of the metal element.

The metal complex can be obtained, for example, by reacting a metal salt with a complexing agent. Examples of a manufacturing method of the metal complex include a method of adding a metal salt and a complexing agent to an organic solvent and stirring the mixture for a predetermined time. The stirring method is not particularly limited, and can be appropriately selected from known methods such as a stirring method using a stirrer, a stirring blade, or a mixer, and a method of applying ultrasonic waves.

Examples of the metal salt include a metal oxide, thiocyanate, sulfide, chloride, cyanide, cyanate, carbonate, acetate, nitrate, nitrite, sulfate, phosphate, perchlorate, tetrafluoroborate, an acetyl acetonate complex salt, and carboxylate.

Examples of the complexing agent include an amine, an ammonium carbamate-based compound, an ammonium carbonate-based compound, an ammonium bicarbonate compound, and a carboxylic acid. Among these, from the viewpoint of conductivity and stability of the metal complex, the complexing agent preferably includes at least one selected from the group consisting of an ammonium carbamate-based compound, an ammonium carbonate-based compound, an amine, and a carboxylic acid having 8 to 20 carbon atoms.

The metal complex has a structure derived from a complexing agent, and preferably has a structure derived from at least one selected from the group consisting of an ammonium carbamate-based compound, an ammonium carbonate-based compound, an amine, and a carboxylic acid having 8 to 20 carbon atoms.

Examples of the amine as a complexing agent include ammonia, a primary amine, a secondary amine, a tertiary amine, and a polyamine.

Examples of the primary amine having a linear alkyl group include methylamine, ethylamine, 1-propylamine, n-butylamine, n-pentylamine, n-hexylamine, heptylamine, octylamine, nonylamine, n-decylamine, undecylamine, dodecylamine, tridecylamine, tetradecylamine, pentadecylamine, hexadecylamine, heptadecylamine, and octadecylamine.

Examples of the primary amine having a branched alkyl group include isopropylamine, sec-butylamine, tert-butylamine, isopentylamine, 2-ethylhexylamine, and tert-octylamine.

Examples of the primary amine having an alicyclic structure include cyclohexylamine and dicyclohexylamine.

Examples of the primary amine having a hydroxyalkyl group include ethanolamine, diethanolamine, triethanolamine, N-methylethanolamine, propanolamine, isopropanolamine, dipropanolamine, diisopropanolamine, tripropanolamine, and triisopropanolamine.

Examples of the primary amine having an aromatic ring include benzylamine, N,N-dimethylbenzylamine, phenylamine, diphenylamine, triphenylamine, aniline, N,N-dimethylaniline, N,N-dimethyl-p-toluidine, 4-aminopyridine, and 4-dimethylaminopyridinc.

Examples of the secondary amine include dimethylamine, diethylamine, dipropylamine, dibutylamine, diphenylamine, dicyclopentylamine, and methylbutylamine.

Examples of the tertiary amine include trimethylamine, triethylamine, tripropylamine, and triphenylamine.

Examples of the polyamine include ethylenediamine, 1,3-diaminopropane, diethylenetriamine, triethylenetetramine, tetramethylenepentamine, hexamethylenediamine, tetraethylenepentamine, and a combination of these.

The amine is preferably an alkylamine, more preferably an alkylamine having 3 to 10 carbon atoms, and still more preferably a primary alkylamine having 4 to 10 carbon atoms.

The metal complex may be configured of one amine or two or more amines.

In reacting the metal salt with an amine, a ratio of the mass of substances of the amine to a mass of substances of the metal salt is preferably 1/1 to 15/1, and more preferably 1.5/1 to 6/1. In a case in which the above ratio is within the above range, the complex formation reaction is completed, and a transparent solution is obtained.

Examples of the ammonium carbamate-based compound as a complexing agent include ammonium carbamate, methylammonium methylcarbamate, ethylammonium ethylcarbamate, 1-propylammonium 1-propylcarbamate, isopropylammonium isopropylcarbamate, butylammonium butylcarbamate,isobutylammonium isobutylcarbamate, amylammonium amylcarbamate, hexylammonium hexylcarbamate, heptylammonium heptylcarbamate, octylammonium octylcarbamate, 2-ethylhexylammonium 2-ethylhexylcarbamate, nonylammonium nonylcarbamate, and decylammonium decylcarbamate.

Examples of the ammonium carbonate-based compound as a complexing agent include ammonium carbonate, methylammonium carbonate, ethylammonium carbonate, 1-propylammonium carbonate, isopropylammonium carbonate, butylammonium carbonate, isobutylammonium carbonate, amylammonium carbonate, hexylammonium carbonate, heptylammonium carbonate, octylammonium carbonate, 2-ethylhexylammonium carbonate, nonylammonium carbonate, and decylammonium carbonate.

Examples of the ammonium bicarbonate-based compound as a complexing agent include ammonium bicarbonate, methylammonium bicarbonate, ethylammonium bicarbonate, 1-propylammonium bicarbonate, isopropylammonium bicarbonate, butylammonium bicarbonate, isobutylammonium bicarbonate, amylammonium bicarbonate, hexylammonium bicarbonate, heptylammonium bicarbonate, octylammonium bicarbonate, 2-ethylhexylammonium bicarbonate, nonylammonium bicarbonate, and decylammonium bicarbonate.

In reacting the metal salt with an ammonium carbamate-based compound, an ammonium carbonate-based compound, or an ammonium bicarbonate-based compound, a ratio of a mass of substances of the ammonium carbamate-based compound, the ammonium carbonate-based compound, or the ammonium bicarbonate-based compound to the mass of substances of the metal salt is preferably 0.01/1 to 1/1, and more preferably 0.05/1 to 0.6/1.

Examples of the carboxylic acid as a complexing agent include caproic acid, caprylic acid, pelargonic acid, 2-ethylhexanoic acid, capric acid, neodecanoic acid, undecanoic acid, lauric acid, myristic acid, palmitic acid, stearic acid, palmitoleic acid, oleic acid, linoleic acid, and linolenic acid. Among these, the carboxylic acid is preferably a carboxylic acid having 8 to 20 carbon atoms, and more preferably a carboxylic acid having 10 to 16 carbon atoms.

The content of the metal complex in the metal complex ink is preferably 10% by mass to 90% by mass, and more preferably 10% by mass to 40% by mass, with respect to the total mass of the metal complex ink. In a case where the content of the metal complex is 10% by mass or more, the surface resistivity is further reduced. In a case where the content of the metal complex is 90% by mass or less, jettability is improved in a case where the metal complex ink is applied with an ink jet recording method.

### —Solvent—

The metal complex ink preferably contains a solvent. The solvent is not particularly limited as long as it can dissolve the component contained in the metal complex ink, such as the metal complex. From the viewpoint of ease of manufacturing, the boiling point of the solvent is preferably 30° C. to 300° C., more preferably 50° C. to 200° C., and still more preferably 50° C. to 150° C.

The solvent is preferably contained in the metal complex ink such that the concentration of metal ions with respect to the metal complex (the amount of the metal present as free ions with respect to 1 g of the metal complex) is 0.01 mmol/g to 3.6 mmol/g, and is more preferably contained in the metal complex ink such that the concentration of metal ions is 0.05 mmol/g to 2 mmol/g. In a case in which the concentration of metal ions is within the above range, the metal complex ink has excellent fluidity and can obtain conductivity.

Examples of the solvent include a hydrocarbon, a cyclic hydrocarbon, an aromatic hydrocarbon, a carbamate, an alkene, an amide, an ether, an ester, an alcohol, a thiol, a thioether, phosphine, and water. The metal complex ink may contain only one solvent or two or more solvents.

The hydrocarbon is preferably a linear or branched hydrocarbon having 6 to 20 carbon atoms. Examples of the hydrocarbon include pentane, hexane, heptane, octane, nonane, decane, undecane, dodecane, tridecane, tetradecane, pentadecane, hexadecane, octadecane, nonadecane, and icosane.

The cyclic hydrocarbon is preferably a cyclic hydrocarbon having 6 to 20 carbon atoms. The cyclic hydrocarbons can include, for example, cyclohexane, cycloheptane, cyclooctane, cyclononane, cyclodecane, and decalin.

Examples of the aromatic hydrocarbon include benzene, toluene, xylene, and tetraline.

The ether may be any of a linear ether, a branched ether, or a cyclic ether. Examples of the ether include diethyl ether, dipropyl ether, dibutyl ether, methyl-t-butyl ether, tetrahydrofuran, tetrahydropyrane, dihydropyrane, and 1,4-dioxane.

The alcohol may be any of a primary alcohol, a secondary alcohol, or a tertiary alcohol.

Examples of the alcohol include ethanol, 1-propanol, 2-propanol, 1-methoxy-2-propanol, 1-butanol, 2-butanol, 1-pentanol, 2-pentanol, 3-pentanol, 1-hexanol, 2-hexanol, 3-hexanol, 1-octanol, 2-octanol, 3-octanol, tetrahydrofurfuryl alcohol, cyclopentanol,terpineol, decanol, isodecyl alcohol, lauryl alcohol, isolauryl alcohol, myristyl alcohol, isomyristyl alcohol, cetyl alcohol (cetanol), isocetyl alcohol, stearyl alcohol, isostearyl alcohol, oleyl alcohol, isooleyl alcohol, linoleyl alcohol, isolinoleyl alcohol, palmityl alcohol, isopalmityl alcohol, icosyl alcohol, and isoicosyl alcohol.

Examples of the ketone include acetone, methyl ethyl ketone, methyl isobutyl ketone, and cyclohexanone.

Examples of the ester include methyl acetate, ethyl acetate, isopropyl acetate, butyl acetate, isobutyl acetate, sec-butyl acetate, methoxybutyl acetate, ethylene glycol monomethyl ether acetate, ethylene glycol monoethyl ether acetate, ethylene glycol monobutyl ether acetate, diethylene glycol monomethyl ether acetate, and diethylene glycol monoethyl ether acetate, diethylene glycol monobutyl ether acetate, propylene glycol monomethyl ether acetate, propylene glycol monoethyl ether acetate, propylene glycol monobutyl ether acetate, dipropylene glycol monomethyl ether acetate, dipropylene glycol monoethyl ether acetate, dipropylene glycol monobutyl ether acetate, and 3-methoxybutyl acetate.

### —Reducing Agent—

The metal complex ink may contain a reducing agent. In a case in which the metal complex ink contains a reducing agent, reduction of the metal complex into a metal is facilitated.

Examples of the reducing agent include a borohydride metal salt, an aluminum hydride salt, an amine, an alcohol, an organic acid, reduced sugar, a sugar alcohol, sodium sulfite, a hydrazine compound, dextrin, hydroquinone, hydroxylamine, ethylene glycol, glutathione, and an oxime compound.

The reducing agent may be the oxime compound described in JP2014-516463A. Examples of the oxime compound include acetone oxime, cyclohexanone oxime, 2-butanone oxime, 2,3-butanedione monoxime, dimethyl glyoxime, methyl acetoacetate monoxime, methyl pyruvate monoxime, benzaldehyde oxime, 1-indanone oxime, 2-adamantanone oxime, 2-methylbenzamide oxime, 3-methylbenzamide oxime, 4-methylbenzamide oxime, 3-aminobenzamide oxime, 4-aminobenzamide oxime, acetophenone oxime, benzamide oxime, and pinacolone oxime.

The metal complex ink may contain one reducing agent or two or more reducing agents.

The content of the reducing agent in the metal complex ink is not particularly limited, but is preferably 0.1% by mass to 20% by mass, more preferably 0.3% by mass to 10% by mass, and still more preferably 1% by mass to 5% by mass, with respect to the total mass of the metal complex ink.

### —Resin—

The metal complex ink may contain a resin. In a case in which the metal complex ink contains a resin, adhesiveness of the metal complex ink to the electronic substrate is improved.

Examples of the resin include polyester, polyethylene, polypropylene, polyacetal, polyolefin, polycarbonate, polyamide, a fluororesin, a silicone resin, ethyl cellulose, hydroxyethyl cellulose, rosin, an acrylic resin, polyvinyl chloride, polysulfone, polyvinylpyrrolidone, polyvinyl alcohol, a polyvinyl-based resin, polyacrylonitrile, polysulfide, polyamideimide, polyether, polyarylate, polyether ether ketone, polyurethane, an epoxy resin, a vinyl ester resin, a phenol resin, a melamine resin, and a urea resin.

The metal complex ink may contain one resin or two or more resins.

### —Additive—

As long as the coverage or the electromagnetic wave shielding properties are not impaired, the metal complex ink may further contain additives such as an inorganic salt, an organic salt, an inorganic oxide such as silica, a surface conditioner, a wetting agent, a crosslinking agent, an antioxidant, a rust inhibitor, a heat-resistant stabilizer, a surfactant, a plasticizer, a curing agent, a thickener, and a silane coupling agent. The total content of the additives in the metal complex ink is preferably 20% by mass or less with respect to the total mass of the metal complex ink.

A viscosity of the metal complex ink is preferably 1 mPa·s to 100 mPa·s, more preferably 2 mPa·s to 50 mPa·s, and still more preferably 3 mPa·s to 30 mPa·s.

The viscosity of the metal complex ink is a value measured at 25° C. using a viscometer. The viscosity is measured using, for example, a VISCOMETER TV-22 type viscometer (manufactured by Toki Sangyo Co., Ltd.).

The surface tension of the metal complex ink is not particularly limited, and is preferably 20 mN/m to 45 mN/m and more preferably 25 mN/m to 35 mN/m. The surface tension is a value measured at 25° C. using a surface tension meter.

The surface tension of the metal complex ink is measured using, for example, DY-700 (manufactured by Kyowa Interface Science Co., Ltd.).

### <<Metal Salt Ink>>

The metal salt ink is, for example, an ink composition obtained by dissolving a metal salt in a solvent.

### —Metal Salt—

Examples of metals constituting the metal salt include silver, copper, gold, aluminum, magnesium, tungsten, molybdenum, zinc, nickel, iron, platinum, tin, and lead. Among these, from the viewpoint of conductivity, the metal constituting the metal salt preferably includes at least one selected from the group consisting of silver, gold, platinum, nickel, palladium, and copper, and more preferably includes silver.

The content of the metal contained in the metal salt ink is preferably 1% by mass to 40% by mass, more preferably 5% by mass to 30% by mass, and still more preferably 7% by mass to 20% by mass, with respect to the total mass of the metal salt ink, in terms of the metal element.

The content of the metal salt in the metal salt ink is preferably 10% by mass to 90% by mass, and more preferably 10% by mass to 40% by mass, with respect to the total mass of the metal salt ink. In a case in which the content of the metal salt is 10% by mass or more, the surface resistivity is further reduced. In a case where the content of the metal salt is 90% by mass or less, jettability is improved in a case where the metal salt ink is applied with an ink jet recording method.

Examples of the metal salt include benzoate, halide, carbonate, citrate, iodate, nitrite, nitrate, acetate, phosphate, sulfate, sulfide, trifluoroacetate, and carboxylate of a metal. Two or more salts may be combined.

From the viewpoint of conductivity and storage stability, the metal salt is preferably a metal carboxylate. The carboxylic acid forming the metal carboxylate is preferably at least one selected from the group consisting of formic acid and a carboxylic acid having 1 to 30 carbon atoms, and more preferably a carboxylic acid having 8 to 20 carbon atoms, and still more preferably a fatty acid having 8 to 20 carbon atoms. The fatty acid may be linear or branched or may have a substituent.

Examples of the linear fatty acid include acetic acid, propionic acid, butyric acid, valeric acid, pentanoic acid, hexanoic acid, heptanoic acid, behenic acid, oleic acid, octanoic acid, nonanoic acid, decanoic acid, caproic acid, enanthic acid, caprylic acid, pelargonic acid, capric acid, and undecanoic acid.

Examples of the branched fatty acid include isobutyric acid, isovaleric acid, ethylhexanoic acid, neodecanoic acid, pivalic acid, 2-methylpentanoic acid, 3-methylpentanoic acid, 4-methylpentanoic acid, 2,2-dimethylbutanoic acid, 2,3-dimethylbutanoic acid, 3,3-dimethylbutanoic acid, and 2-ethylbutanoic acid.

Examples of the carboxylic acid having a substituent include hexafluoroacetylacetonate, hydroangelate, 3-hydroxybutyric acid, 2-methyl-3-hydroxybutyric acid, 3-methoxybutyric acid, acetonedicarboxylic acid, 3-hydroxyglutaric acid, 2-methyl-3-hydroxyglutaric acid, and 2,2,4,4-hydroxyglutaric acid.

The metal salt may be a commercially available product or may be manufactured by a known method. A silver salt is manufactured, for example, by the following method.

First, a silver compound (for example, silver acetate) functioning as a silver supply source and formic acid or a fatty acid having 1 to 30 carbon atoms in the same quantity as the molar equivalent of the silver compound are added to an organic solvent such as ethanol. The mixture is stirred for a predetermined time using an ultrasonic stirrer, and the formed precipitate is washed with ethanol and decanted. All of these steps can be performed at room temperature (25° C.). A mixing ratio of the silver compound and the formic acid or fatty acid having 1 to 30 carbon atoms is preferably 1:2 to 2:1, and more preferably 1:1, in terms of molar ratio.

—Other components—

The metal salt ink may contain a solvent, a reducing agent, a resin, and additives. Preferred aspects of the solvent, the reducing agent, the resin, and the additives are the same as the preferred aspects of the solvent, the reducing agent, the resin, and the additives which may be contained in the metal complex ink.

### —Physical Properties of Metal Salt Ink—

A viscosity of the metal salt ink is preferably 1 mPa·s to 100 mPa·s, more preferably 2 mPa·s to 50 mPa·s, and still more preferably 3 mPa·s to 30 mPa·s.

The viscosity of the metal salt ink is a value measured at 25° C. by using a viscometer. The viscosity is measured using, for example, a VISCOMETER TV-22 type viscometer (manufactured by Toki Sangyo Co., Ltd.).

The surface tension of the metal salt ink is not particularly limited, and is preferably 20 mN/m to 45 mN/m and more preferably 25 mN/m to 35 mN/m. The surface tension is a value measured at 25° C. using a surface tension meter.

The surface tension of the metal salt ink is measured using, for example, DY-700 (manufactured by Kyowa Interface Science Co., Ltd.).

### (Application of Conductive Ink)

The applying method of the conductive ink is an ink jet recording method at the same time as the insulating ink. In the ink jet recording method, a small amount of the conductive ink is jetted, so that a thickness of the electromagnetic wave shielding layer formed by one application can be reduced.

Since preferred aspect of the ink jet recording method is the same as the preferred aspect of the ink jet recording method in the application of the insulating ink, the detailed description thereof will be omitted.

It is preferable to preheat the printed wiring board on which the insulating layer is formed, before applying the conductive ink. A temperature of the printed wiring board in a case of applying the conductive ink is preferably 20° C. to 120° C., and more preferably 40° C. to 100° C.

In a case of forming the electromagnetic wave shielding layer, as described above, the conductive ink is applied onto the insulating layer and at least a part of the ground wiring line to form the electromagnetic wave shielding layer, which is a cured film of the conductive ink.

As described above, the insulating ink is jetted with an ink jet onto the insulating layer to form the electromagnetic wave shielding layer. In this case, the electromagnetic wave shielding layer is formed to be in contact with at least a part of the ground wiring line. As a result, a current generated by the incidence of the electromagnetic wave on the electromagnetic wave shielding layer flows to the ground, and the electromagnetic wave can be attenuated.

In a case of forming the electromagnetic wave shielding layer, a position and a disposition shape of the ground wiring line for forming the insulating layer are measured in advance, for example, with a microscope to obtain disposition information of the ground wiring line. It is preferable to set the application region of the conductive ink and the number of applications of the conductive ink based on the disposition information.

For example, the three-dimensional shape data of the processing substrate 11 described above can also be used for forming the electromagnetic wave shielding layer. In this case, the solid image in which all the first images Im₁ shown in FIG. 7 described above are configured as the image area can be used as a print image of the electromagnetic wave shielding layer. After forming the insulating layer, the conductive ink can be jetted onto the insulating layer using the print image of the electromagnetic wave shielding layer described above to form the electromagnetic wave shielding layer.

### (Formation of Electromagnetic Wave Shielding Layer)

It is preferable that the conductive ink is cured using heat or light after being applied onto the insulating layer.

In a case where the conductive ink is cured using heat, it is preferable that a baking temperature is 250° C. or lower, and a baking time is 1 minute to 120 minutes. In a case where the baking temperature and the baking time are in the above ranges, the damage to the electronic substrate is suppressed.

The baking temperature is preferably 80° C. to 250° C., and more preferably 100° C. to 200° C. The baking time is preferably 1 minute to 60 minutes.

The baking method is not particularly limited, and a generally known method can be used.

A time from a time point at which the application of the conductive ink is completed to a time point at which the baking is started is preferably 60 seconds or less. The lower limit value of the time described above is not particularly limited, but is, for example, 20 seconds. In a case where the time is 60 seconds or less, the conductivity is improved.

The phrase “time point at which the application of the conductive ink is completed” refers to a time point at which all the droplets of the conductive ink have been landed on the insulating layer.

In a case where the conductive ink is cured using light, examples of the light include ultraviolet rays and infrared rays.

A peak wavelength of the ultraviolet rays is preferably 200 nm to 405 nm, more preferably 250 nm to 400 nm, and still more preferably 300 nm to 400 nm.

An exposure amount during the light irradiation is preferably 100 mJ/cm² to 10,000 mJ/cm², and more preferably 500 mJ/cm² to 7,500 mJ/cm².

The present invention is basically configured as described above. The manufacturing method of a printed circuit board according to the embodiment of the present invention has been described in detail above, but the present invention is not limited to the above-described embodiments, and various improvements and changes can be made without departing from the spirit of the present invention.

### EXAMPLES

Hereinafter, characteristics of the present invention will be described in further detail with reference to examples. Any materials, reagents, mass of substances and their ratios, operations and so forth shown in Example below may appropriately be altered, without departing from the spirit of the present invention. Accordingly, the scope of the present invention is not limited to the following example.

In the present example, an insulating layer and an electromagnetic wave shielding layer were formed on a printed wiring board A on which a semiconductor device shown below was mounted, and a defect of the surface coating of the electromagnetic wave shielding layer and the electromagnetic wave shielding properties were evaluated.

As the printed wiring board A, a long term evolution (LTE) substrate BG96 (trade name) manufactured by Quectel Wireless Solutions Co., Ltd. was used. The printed wiring board A includes a region surrounded by a ground wiring line.

There are a plurality of semiconductor devices, and among these, there is a semiconductor device having a vertical surface perpendicular to the surface of the printed wiring board A. The semiconductor device is a laminated capacitor, a quartz oscillator, or an integrated circuit. There was a semiconductor device having a height of 0.9 mm.

In addition, the semiconductor device is mounted in a region surrounded by a ground wiring line. The shortest distance between the ground wiring line of the printed wiring board A and the semiconductor device was 0.3 mm.

The printed wiring board A is a communication module on which a semiconductor device having a height of 0.9 mm is mounted, and is used by being connected to a circuit that drives the communication module and an antenna in a case of communication.

Hereinafter, the insulating ink 1 used for forming the insulating layer and the conductive inks 1 and 2 used for forming the electromagnetic wave shielding layer will be described.

### <Insulating Ink 1>

4.0 g of 2-(dimethylamino)-2-(4-methylbenzyl)-1-(4-morpholinophenyl)-butan-1-one (trade name “Omnirad 379”, manufactured by IGM Resins B.V.), 2.0 g of 2-isopropylthioxantone (trade name “SPEEDCURE ITX”, manufactured by LAMBSON Ltd.), 30.0 g of isobornyl acrylate (manufactured by FUJIFILM Wako Pure Chemical Corporation), 20.0 g of N-vinylcaprolactam, 10.0 g of 1,6-hexanediol diacrylate, 9.0 g of cyclohexanedimethanol diacrylate (manufactured by Tokyo Chemical Industry Co., Ltd.), and 9.0 g of trimethylolpropane triacrylate (manufactured by FUJIFILM Wako Pure Chemical Corporation) were added to a 300 mL resin beaker, and the mixture was stirred for 20 minutes at a temperature of 25° C. under the conditions of 5000 rpm using a mixer (trade name “L4R”, manufactured by Silverson), thereby obtaining an insulating ink 1.

### <Conductive Ink 1>

6.08 g of isobutylammonium carbonate and 15.0 g of isopropyl alcohol were added to a three-neck flask of 50 mL, and dissolved. Next, 2.0 g of silver oxide was added thereto and reacted at a normal temperature for 2 hours, thereby obtaining a homogeneous solution. Furthermore, 0.3 g of 2-hydroxy-2-methylpropylamine was added thereto and stirred, thereby obtaining a solution containing a silver complex. This solution was filtered using a membrane filter made of polytetrafluoroethylene (PTFE) having a pore diameter of 0.45 μm, thereby obtaining a conductive ink 1. The conductive ink is a silver complex ink.

### <Conductive Ink 2>

### (Silver Particle Ink)

### —Preparation of Silver Particle Dispersion 1—

As a dispersing agent, 6.8 g of polyvinylpyrrolidone (weight-average molecular weight: 3,000, manufactured by Sigma-Aldrich Corporation) was dissolved in 100 mL of water, thereby preparing a solution a. In addition, 50.00 g of silver nitrate was dissolved in 200 mL of water, thereby preparing a solution b. The solution a and the solution b were mixed together and stirred, thereby obtaining a mixed solution. At a room temperature, 78.71 g of an 85% by mass N,N-diethylhydroxylamine aqueous solution was added dropwise to the mixed solution. In addition, a solution obtained by dissolving 6.8 g of polyvinylpyrrolidone in 1,000 mL of water was slowly added dropwise to the mixed solution at a room temperature. The obtained suspension was passed through an ultrafiltration unit (VIVAFLOW 50 manufactured by Sartorius Stedim Biotech GmbH., molecular weight cut-off: 100,000, number of units: 4) and purified by being passed through purified water until about 5 L of exudate is discharged from an ultrafiltration unit. The supply of purified water was stopped, followed by concentration, thereby obtaining 30 g of a silver particle dispersion 1. The solid content in the solid content in the silver particle dispersion 1 was 50% by mass, and the content of the silver in the solid content measured by TG-DTA (simultaneous measurement of thermogravimetry and differential thermal analysis) (manufactured by Hitachi High-Tech Corporation., model: STA 7000 series), was 96.0% by mass. The obtained silver particle dispersion 1 was diluted 20-fold with deionized water, and measured using a particle size analyzer FPAR-1000 (manufactured by Otsuka Electronics Co., Ltd) to obtain a volume average particle size of the silver particles. The volume average particle size of the silver particles in the silver particle dispersion 1 was 60 nm.

### —Adjustment of Silver Particle Ink—

2 g of 2-propanol and 0.1 g of OLFINE E-1010 (manufactured by Nissin Chemical Industry Co., Ltd.) as a surfactant were added to 10 g of the silver particle dispersion 1, and water was added thereto such that the silver concentration reaches 40% by mass, thereby obtaining a silver particle ink as the conductive ink 2. The conductive ink 2 is a silver nano ink.

### <Preparation of Print Image>

A three-dimensional shape of the printed wiring board A was imaged with a microscope VHX-7000 (KEYENCE CORPORATION). Slice data at a height of 0.3 mm, 0.6 mm, and 0.9 mm from the substrate was output, and the slice data was converted into a reversed image in which a portion including the semiconductor device was white. An outer edge of the image having a height of 0.3 mm was matched with an inner side of the ground wiring line (image 1). In an image having a height of 0.6 mm, an outer edge was set to be smaller by 0.1 mm from the inner side of the ground (image 2). In an image having a height of 0.9 mm, an outer edge was set to be smaller by 0.2 mm inward (image 3). Furthermore, as the image to be printed on the upper surface, a solid image (image 4) in which the outer edge was set 0.3 mm inward from the ground was prepared.

As the print image of the electromagnetic wave shielding layer, a solid image (image 5) in which entire portions inside the outer peripheral portion of the ground wiring line was prepared.

As the image at a height of 0.6 to 0.9 mm of the printed image of the insulating layer and the upper parts of the print image of the insulating layer, each of an image 6, an image 7, and an image 8 were prepared by preparing the outer edge to be aligned with the inner side of the ground wiring line.

A relationship between a distance from the ground wiring line of the prepared print image and a height from the surface of the printed wiring board is shown in Table 1 below.

TABLE 1

| | Distance from ground wiring line (mm) | | | | | | |
|---|---|---|---|---|---|---|---|
| | 0 | 0.05 | 0.1 | 0.15 | 0.2 | 0.25 | 0.3 |
| Height 0.3 mm | Image 1 | — | — | — | — | — | — |
| Height 0.45 mm | — | Image 12 | Image 13 | — | — | — | — |
| Height 0.6 mm | Image 6 | Image 9 | Image 2 | Image 18 | — | — | — |
| Height 0.75 mm | Image 14 | — | — | Image 17 | Image 15 | — | — |
| Height 0.9 mm | Image 7 | — | — | Image 10 | Image 3 | Image 16 | — |
| Solid image | Image 8 | — | — | — | Image 19 | Image 11 | Image 4 |

Hereinafter, Examples 1 to 7 and Comparative Examples 1 and 2 will be described.

### Example 1

### <Formation of Insulating Layer>

An insulating layer was formed on the printed wiring board A on which the semiconductor device was mounted, using the above-described insulating ink 1, based on the above-described images 1 to 4.

The above-described insulating ink 1 (insulating active energy-curable-type ink) was charged into an ink cartridge (10 picoliters) for an ink jet recording device (trade name “DMP-2850”, manufactured by FUJIFILM DIMATIX Inc.). An image recording condition was set such that a resolution was 2,510 dots per inch (dpi), an amount of droplets was 10 picoliters per dot, a jetting frequency was 16 kHz, and a jetting temperature was 45° C. UV spot curing Omni Cure S2000 (manufactured by Lumen Dynamics Group Inc.) was prepared by being attached to a location 7 cm away from the ink jet nozzle position, next to the head of the ink jet recording device. The printing was performed after the position of the printed wiring board A and the position of the print image were adjusted to correspond to each other. During the printing, the ink was cured by being exposed to UV light at an illuminance of 4 W/cm² for 1.5 seconds. Each of the image 1, the image 2, the image 3, and the image 4 was printed in 16 layers to form an insulating layer. It was confirmed that the insulating layer was formed inside the ground wiring line and all the semiconductor devices inside the ground wiring line were embedded in the insulating layer.

Images 1 to 19 shown in Table 1 described above were set such that the images 1 to 19 were printed in 16 layers by the ink jet so as to form a layer having a height of 0.3 mm. Therefore, in a case of 8 layers, a layer having a height of 0.15 m is formed, and in a case of 24 layers, a layer having a height of 0.45 mm is formed.

### <Formation of Electromagnetic Wave Shielding Layer>

The conductive ink 1 was charged into the ink cartridge for an ink jet recording device used for forming the above-described insulating layer. An image recording condition was set such that a resolution was 2,510 dots per inch (dpi), an amount of droplets was 10 picoliters per dot, a jetting frequency was 4 kHz, and a head temperature was 30° C. The printed wiring board A on which the insulating layer was formed was heated with a temperature of a platen set to 60° C. A printing pattern of a solid image having the same dimensions as the outer edge of the ground wiring line was printed on the ground wiring line and the insulating layer with an ink jet, with the printing origin aligned with the upper left end of the ground wiring line on the frame. After the printing, the printed wiring board was placed in an oven at a temperature of 160° C. and heated for 30 minutes. The electromagnetic wave shielding layer was formed by the heat treatment performed on the printed wiring board.

### Examples 2 to 7, and Comparative Examples 1 and 2

In Examples 2 to 7, and Comparative Examples 1 and 2, the insulating layer and the electromagnetic wave shielding layer were formed using the insulating ink and the conductive ink shown in Table 2, in comparison with Example 1. In addition, in the formation of the insulating layer, using the image of the column of the insulating layer shown in Table 2 below, a printed circuit board was produced for each image in the same manner as in Example 1, except for a point that the number of printing layers described in parentheses are printed. The number of layers in parentheses in Table 2 below indicates the number of printing layers of one print image. The number of printing layers indicates the number of repetitions of printing on one print image.

In Comparative Examples 1 and 2, the outer edge of the jetting region of the insulating ink is not gradually reduced to form the insulating layer.

For Example 1 to Example 7, and Comparative Examples 1 and 2, the maximum angle of the inclined part, the defect of the surface coating of the electromagnetic wave shielding layer, and the electromagnetic wave shielding properties were evaluated. The results thereof are shown in Table 2 below.

### <Maximum Angle of Inclined Part>

A three-dimensional shape of the produced printed circuit board was measured with a laser microscope VK-X1000 (manufactured by KEYENCE CORPORATION, magnification: 100 times, 3D connection mode), and an angle between an inclined part of the insulating layer formed between the semiconductor device and the ground wiring line and the printed wiring board was measured at nine points, and the maximum value thereof was defined as the maximum angle of the inclined part.

The above-described nine measurement points are randomly selected, but for the measurement point, a portion where a value of the height of the insulating layer is larger than a value of the distance corresponding to the above-described distance Xm (refer to FIG. 1) between the measurement point and the ground wiring line is included in the measurement point. In addition, since the inclination angle of the inclined part changes depending on the orientation of the inclined part or the height of the peripheral member, the inclination angle was measured in a vertical direction with respect to the outer frame portion of the insulating layer at the measurement point, and the measurement was performed for a plurality of inclined parts instead of one inclined part. In the printed wiring board A on which the above-described semiconductor device is mounted, a portion between the quartz oscillator or the integrated circuit and the ground is maximum inclination.

### <Defects in Surface Coating>

An electromagnetic wave shielding layer of the produced printed circuit board was imaged with a microscope VHX-7000 (manufactured by KEYENCE CORPORATION, magnification: 100 times, 3D connection mode) to acquire an enlarged image of the entire printed wiring board A (communication module), and among the defects in the surface coating of the electromagnetic wave shielding layer, defects having a size of a length of 0.1 to 1.0 mm were evaluated. The number of defects to be evaluated was evaluated using the following evaluation standard. In the following evaluation standard, in the evaluation of the defects of the surface coating, the rank of the most excellent is 5.

### —Evaluation Standard of Defects in Surface Coating—

5: the number of defects to be evaluated is 0 (no defect).
4: the number of defects to be evaluated is 1.
3: the number of defects to be evaluated is 2.
2: the number of defects to be evaluated is 3 or more and less than 5.
1: the number of defects to be evaluated is 5 or more, or the defect including a crack having a size of more than 1.0 mm.

### <Electromagnetic Wave Shielding Properties>

The produced printed circuit board was allowed to communicate with LTE BAND13, and the measurement of the magnetic field in the vicinity was carried out at a frequency of 777 MHz using a near magnetic field measuring device (trade name “SmartScan550”, manufactured by API Co., Ltd.). A noise suppression level (unit: dB) in the near magnetic field measurement was measured, and the electromagnetic wave shielding properties were evaluated based on the obtained noise suppression level according to the following evaluation standard. In the following evaluation standard, the rank of the most excellent electromagnetic wave shielding properties is 5.

### —Evaluation Standard for Electromagnetic Wave Shielding Properties—

5: noise suppression level is −40 dB or less.
4: noise suppression level is more than −40 dB and −30 dB or less.
3: noise suppression level is more than −30 dB and −20 dB or less.
2: noise suppression level is more than −20 dB and −10 dB or less.
1: noise suppression level is more than −10 dB.

| | | Example 1 | Example 2 | Example 3 | Example 4 | Example 5 |
|---|---|---|---|---|---|---|
| Insulating ink | | Insulating | Insulating | Insulating | Insulating | Insulating |
| | | ink 1 | ink 1 | ink 1 | ink 1 | ink 1 |
| Conductive ink | | Conductive | Conductive | Conductive | Conductive | Conductive |
| | | ink 1 | ink 2 | ink 2 | ink 2 | ink 2 |
| Insulating | First | Image 1 (16 | Image 1 (16 | Image 1 (16 | Image 1 (16 | Image 1 (8 |
| layer | layer | layers) | layers) | layers) | layers) | layers) |
| | Second | Image 2 (16 | Image 9 (16 | Image 2 (8 | Image 12 (8 | Image 12 (8 |
| | layer | layers) | layers) | layers) | layers) | layers) |
| | Third | Image 3 (16 | Image 10 (16 | Image 15 (8 | Image 2 (8 | Image 13 (8 |
| | layers | layers) | layers) | layers) | layers) | layers) |
| | Fourth | Image 4 (16 | Image 4 (16 | Image 16 (16 | Image 17 (8 | Image 18 (8 |
| | layers | layers) | layers) | layers) | layers) | layers) |
| | Fifth | — | — | Image 4 (16 | Image 3 (8 | Image 15 (8 |
| | Layers | | | layers) | layers) | layers) |
| | Sixth | — | — | — | Image 4 (16 | Image 16 (8 |
| | layers | | | | layers) | layers) |
| | Seventh | — | — | — | — | Image 4 (16 |
| | layers | | | | | layers) |

| | | | | | |
|---|---|---|---|---|---|
| Conductive layers | Image 5 | Image 5 | Image 5 | Image 5 | Image 5 |
| Maximum value of inclination | 75 | 79 | 72 | 70 | 65 |
| angle (°) | | | | | |
| Deflects in surface coating | 4 | 4 | 5 | 5 | 5 |
| Electromagnetic wave shielding | 4 | 3 | 4 | 5 | 5 |
| properties | | | | | |

| | | | | Comparative | Comparative |
|---|---|---|---|---|---|
| | | Example 6 | Example 7 | Example 1 | Example 2 |
| Insulating ink | | Insulating | Insulating | Insulating | Insulating |
| | | ink 1 | ink 1 | ink 1 | ink 1 |
| Conductive ink | | Conductive | Conductive | Conductive | Conductive |
| | | ink 2 | ink 2 | ink 2 | ink 2 |
| Insulating | First | Image 1 (24 | Image 1 (16 | Image 1 (16 | Image 8 (84 |
| layer | layer | layers) | layers) | layers) | layers) |
| | Second | Image 18 (24 | Image 6 (16 | Image 6 (16 | — |
| | layer | layers) | layers) | layers) | |
| | Third | Image 4 (16 | Image 7 (16 | Image 7 (16 | — |
| | layers | layers) | layers) | layers) | |
| | Fourth | — | Image 19 (16 | Image 3 (16 | — |
| | layers | | layers) | layers) | |
| | Fifth | — | — | — | — |
| | Layers | | | | |
| | Sixth | — | — | — | — |
| | layers | | | | |
| | Seventh | — | — | — | — |
| | layers | | | | |

| | | | | |
|---|---|---|---|---|
| Conductive layers | Image 5 | Image 5 | Image 5 | Image 5 |
| Maximum value of inclination | 83 | 82 | 86 | 88 |
| angle (°) | | | | |
| Deflects in surface coating | 3 | 3 | 2 | 1 |
| Electromagnetic wave shielding | 3 | 3 | 1 | 1 |
| properties | | | | |

As shown in Table 2, in Examples 1 to 7, the outer edge of the jetting region of the insulating ink was gradually reduced to form a layer such that the inclined part was formed, the insulating layer was formed, the coverage of the electromagnetic wave shielding layer was good, the number of surface defects were small, and the electromagnetic wave shielding properties were excellent, as compared with Comparative Example 1 and Comparative Example 2.

From Examples 1 to 7, in a case where the maximum angle of the inclined part was 75° or less, the number of defects in the surface coating was small and the electromagnetic wave shielding properties were excellent.

### EXPLANATION OF REFERENCES

10: printed wiring board
10a, 22a, 24a, 26a: surface
11: processing substrate
12: ground wiring line
14: semiconductor device
14a: upper surface
14c: side surface
15: semiconductor device
16: insulating layer
16b: inclined part
16c, 22c, 24c, 26c, 28c: outer edge
17: semiconductor device
18: electromagnetic wave shielding layer
20: printed circuit board
21: image set
22: first layer
24: second layer
26: third layer
28: fourth layer
30, 32a, 32b, 32c: semiconductor device
40, 42: ground wiring line
44, 46, 48: semiconductor device
45a, 45b, 47a, 47b: electronic component
D: region
D₁: first region
D₂: second region
D₃: third region
Dm: image area
H: height
Im₁: first image
Im₂: second image
Im₃: third image
Im₄: fourth image
L: length
NDm: non-image area
Tm: thickness
X: direction
Xm: distance
Y direction

What is claimed is:

1. A manufacturing method of a printed circuit board that includes
a printed wiring board having a ground wiring line,
at least one semiconductor device mounted in a region surrounded by the ground wiring line on the printed wiring board,
an insulating layer that embeds at least one of the semiconductor device, is disposed in the region surrounded by the ground wiring line, and has an inclined part at an outer edge, and
an electromagnetic wave shielding layer disposed on the insulating layer, the method comprising:
a step of forming, on the printed wiring board on which the semiconductor device is mounted, a layer by gradually reducing an outer edge of a jetting region of an insulating ink such that the inclined part is formed to form the insulating layer having the inclined part, in a case where the layer is laminated by performing a step of forming the layer by jetting the insulating ink with an ink jet a plurality of times; and
a step of forming, on the insulating layer, the electromagnetic wave shielding layer by jetting a conductive ink with an ink jet.

2. The manufacturing method of a printed circuit board according to claim 1, wherein a shortest distance between the semiconductor device and the ground wiring line is 0.2 to 1.0 mm.

3. The manufacturing method of a printed circuit board according to claim 1, wherein the inclined part has a maximum angle of 85° or less.

4. The manufacturing method of a printed circuit board according to claim 1, wherein the inclined part has a maximum angle of 75° or less.

5. The manufacturing method of a printed circuit board according to claim 1, wherein the semiconductor device has a side surface perpendicular to a surface of the printed wiring board, and a height of the semiconductor device from the surface of the printed wiring board is 0.5 mm or more.

6. The manufacturing method of a printed circuit board according to claim 2, wherein the inclined part has a maximum angle of 85° or less.

7. The manufacturing method of a printed circuit board according to claim 2, wherein the inclined part has a maximum angle of 75° or less.

8. The manufacturing method of a printed circuit board according to claim 2, wherein the semiconductor device has a side surface perpendicular to a surface of the printed wiring board, and a height of the semiconductor device from the surface of the printed wiring board is 0.5 mm or more.

9. The manufacturing method of a printed circuit board according to claim 3, wherein the inclined part has a maximum angle of 75° or less.

10. The manufacturing method of a printed circuit board according to claim 3, wherein the semiconductor device has a side surface perpendicular to a surface of the printed wiring board, and a height of the semiconductor device from the surface of the printed wiring board is 0.5 mm or more.

11. The manufacturing method of a printed circuit board according to claim 4, wherein the semiconductor device has a side surface perpendicular to a surface of the printed wiring board, and a height of the semiconductor device from the surface of the printed wiring board is 0.5 mm or more.
